(19) United States
(12) Patent Application Publication
(10) Pub. No.: US 2024/0187139 A1
(43) Pub. Date: Jun. 6, 2024

(54) APPLYING NETWORK CODING AT ONE OR MORE MULTICAST RADIO BEARER (MRB) PATHS IN A MULTICAST AND BROADCAST SERVICE (MBS) SYSTEM

(71) Applicant: QUALCOMM Incorporated, San Diego, CA (US)

(72) Inventors: Kangqi LIU, San Diego, CA (US); Ruiming ZHENG, Beijing (CN); Changlong XU, Beijing (CN)

(21) Appl. No.: 18/554,621

(22) PCT Filed: Jun. 24, 2021
(86) PCT No.: PCT/CN2021/102035

§ 371 Date: Oct. 9, 2023

(51) Int. Cl. H04L 1/1812; H04W 28/04

(52) U.S. Cl. CPC H04L 1/1816; H04W 28/04

(57) ABSTRACT

A method for wireless communication performed by a user equipment (UE) includes receiving, from a network device, an initial transmission parameter that indicates whether a network coding function is enabled for initial transmissions from a first radio link control (RLC) entity associated with a multicast radio bearer (MRB) of a network device and a retransmission parameter that indicates whether the network coding function is enabled for retransmissions from a second RLC entity associated with the MRB. The method also includes receiving a set of initial data units from the first RLC entity. The method further includes receiving, from the second RLC entity, a set of retransmission data units based on transmitting status indicators that indicate the set of initial data units satisfy a failure condition.

### FIELD OF THE DISCLOSURE

This disclosure relates generally to wireless communication, and specifically, to applying network coding at one or more multicast radio bearer (MRB) paths in a multicast and broadcast service (MBS) system.

### BACKGROUND

Wireless communication systems are widely deployed to provide various telecommunications services such as telephony, video, data, messaging, and broadcasts. Typical wireless communication systems may employ multiple-access technologies capable of supporting communications with multiple users by sharing available system resources (for example, bandwidth, transmit power, and/or the like). Examples of such multiple-access technologies include code division multiple access (CDMA) systems, time division multiple access (TDMA) systems, frequency-division multiple access (FDMA) systems, orthogonal frequency-division multiple access (OFDMA) systems, single-carrier frequency-division multiple access (SC-FDMA) systems, time division synchronous code division multiple access (TD-SCDMA) systems, and long term evolution (LTE). LTE/LTE-Advanced is a set of enhancements to the universal mobile telecommunications system (UMTS) mobile standard promulgated by the Third Generation Partnership Project (3GPP).

A wireless communication network may include a number of base stations (BSs) that can support communications for a number of user equipment (UEs). A user equipment (UE) may communicate with a base station (BS) via the downlink and uplink. The downlink (or forward link) refers to the communications link from the BS to the UE, and the uplink (or reverse link) refers to the communications link from the UE to the BS. As will be described in more detail, a BS may be referred to as a Node B, a gNB, an access point (AP), a radio head, a transmit and receive point (TRP), a new radio (NR) BS, a 5G Node B, and/or the like.

The above multiple access technologies have been adopted in various telecommunications standards to provide a common protocol that enables different user equipment to communicate on a municipal, national, regional, and even global level. New radio (NR), which may also be referred to as 5G, is a set of enhancements to the LTE mobile standard promulgated by the Third Generation Partnership Project (3GPP). NR is designed to better support mobile broadband Internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink (DL), using CP-OFDM or SC-FDM (for example, also known as discrete Fourier transform spread OFDM (DFT-s-OFDM)) on the uplink (UL), as well as supporting beamforming, multiple-input multiple-output (MIMO) antenna technology, and carrier aggregation.

A multicast and broadcast service (MBS) system may be an example of a point-to-multipoint communication system where packets may be transmitted from a single source to multiple destinations. In some examples, the MBS system may broadcast packets to all receiving devices, such as user equipment (UEs), within an MBS zone. In other examples, the MBS system may multicast packets to a specific group of UEs selected from all UEs in the MBS zone. The MBS zone may be an example of a geographical area served by one or more base stations capable of MBS. The one or more base stations serving an MBS zone may transmit the same content to the UEs in the MBS zone.

In some systems, forward error correction (FEC) coding may be specified to transform an original message of k symbols into a longer message with n symbols, such that the original message may be recovered from a subset of the n symbols. A fountain code is an example of a type of FEC code. A system applying a fountain code may generate a potentially limitless sequence of encoded packets from a set of source packets. In such examples, the set of source packets may be recovered from any subset of the encoded packets when a quantity of encoded packets is greater than the quantity of source packets. Fountain codes may be considered rateless codes because a quantity of packets encoded based on the fountain code may be limitless. In some wireless systems, a fountain code may be referred to as a network code because the fountain code may be applied in a network layer. A Raptor code and a RaptorQ code are examples of a fountain code.

### SUMMARY

In one aspect of the present disclosure, a method for wireless communication by a user equipment (UE) includes receiving, from a network device, radio resource control (RRC) signaling comprising an initial transmission parameter that indicates whether a network coding function is enabled for an initial transmission from a first radio link control (RLC) entity associated with a multicast radio bearer (MRB) and a retransmission parameter that indicates whether the network coding function is enabled for a retransmission from a second RLC entity associated with the MRB. The method further includes receiving, from the first RLC entity of the network device, the initial transmission. The method still further includes transmitting, to the network device, a status data unit. The method also includes receiving, from the second RLC entity of the network device, the retransmission comprising a set of retransmission data units.

Another aspect of the present disclosure is directed to an apparatus for wireless communication at a UE. The apparatus includes means for receiving, from a network device, RRC signaling comprising an initial transmission parameter that indicates whether a network coding function is enabled for an initial transmission from a first RLC entity associated with an MRB and a retransmission parameter that indicates whether the network coding function is enabled for a retransmission from a second RLC entity associated with the MRB. The apparatus further includes means for receiving, from the first RLC entity of the network device, the initial transmission. The apparatus still further includes means for transmitting, to the network device, a status data unit comprising a set of status indicators. The apparatus also includes means for receiving, from the second RLC entity of the network device, the retransmission comprising a set of retransmission data units.

In another aspect of the present disclosure, a non-transitory computer-readable medium with non-transitory program code recorded thereon for wireless communication at a UE is disclosed. The program code is executed by a processor and includes program code to receive, from a network device, RRC signaling comprising an initial transmission parameter that indicates whether a network coding function is enabled for an initial transmission from a first RLC entity associated with a multicast radio bearer (MRB) and a retransmission parameter that indicates whether the network coding function is enabled for a retransmission from a second RLC entity associated with the MRB. The program code further includes program code to receive, from the first RLC entity of the network device, the initial transmission. The program code still further includes program code to transmit, to the network device, a status data unit comprising a set of status indicators. The program code also includes program code to receive, from the second RLC entity of the network device, the retransmission comprising a set of retransmission data units.

Another aspect of the present disclosure is directed to an apparatus for wireless communication at a UE. The apparatus may include a processor, a memory coupled with the processor, and instructions stored in the memory and operable, when executed by the processor, to cause the apparatus to receive, from a network device, RRC signaling comprising an initial transmission parameter that indicates whether a network coding function is enabled for an initial transmission from a first RLC entity associated with an MRB and a retransmission parameter that indicates whether the network coding function is enabled for a retransmission from a second RLC entity associated with the MRB. Execution of the instructions further cause the apparatus to receive, from the first RLC entity of the network device, the initial transmission. Execution of the instructions also cause the apparatus to transmit, to the network device, a status data unit comprising a set of status indicators. Execution of the instructions still further cause the apparatus to receive, from the second RLC entity of the network device, the retransmission comprising a set of retransmission data units.

In one aspect of the present disclosure, a method for wireless communication by a network device includes transmitting, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. The method further includes transmitting, from the first RLC entity to the UE, a set of initial data units associated with the initial transmission. The method still further includes receiving, from the UE, a status data unit comprising a set of status indicators. The method also includes transmitting, from the second RLC entity to the UE, a set of retransmission data units associated with the retransmission.

Another aspect of the present disclosure is directed to an apparatus for wireless communication at a network device. The apparatus includes means for transmitting, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. The apparatus further includes means for transmitting, from the first RLC entity to the UE, a set of initial data units associated with the initial transmission. The apparatus still further includes means for receiving, from the UE, a status data unit comprising a set of status indicators. The apparatus also includes means for transmitting, from the second RLC entity to the UE, a set of retransmission data units associated with the retransmission.

In another aspect of the present disclosure, a non-transitory computer-readable medium with non-transitory program code recorded thereon for wireless communication at a network device is disclosed. The program code is executed by a processor and includes program code to transmit, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. The program code further includes program code to transmit, from the first RLC entity to the UE, a set of initial data units associated with the initial transmission. The program code still further includes program code to receive, from the UE, a status data unit comprising a set of status indicators. The program code also includes program code to transmit, from the second RLC entity to the UE, a set of retransmission data units associated with the retransmission.

Another aspect of the present disclosure is directed to an apparatus for wireless communication at a network device. The apparatus includes a processor, a memory coupled with the processor, and instructions stored in the memory and operable, when executed by the processor, to cause the apparatus to transmit, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. Execution of the instructions also cause the apparatus to transmit, from the first RLC entity to the UE, a set of initial data units associated with the initial transmission. Execution of the instructions further cause the apparatus to receive, from the UE, a status data unit comprising a set of status indicators. Execution of the instructions also cause the apparatus to transmit, from the second RLC entity to the UE, a set of retransmission data units associated with the retransmission.

Aspects generally include a method, apparatus, system, computer program product, non-transitory computer-readable medium, user equipment, base station, wireless communication device, and processing system as substantially described with reference to and as illustrated by the accompanying drawings and specification.

The foregoing has outlined rather broadly the features and technical advantages of examples according to the disclosure in order that the detailed description that follows may be better understood. Additional features and advantages will be described. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that features of the present disclosure can be understood in detail, a particular description may be had by reference to aspects, some of which are illustrated in the appended drawings. It is to be noted, however, that the appended drawings illustrate only certain aspects of this disclosure and are therefore not to be considered limiting of its scope, for the description may admit to other equally effective aspects. The same reference numbers in different drawings may identify the same or similar elements.

FIG. 1 is a block diagram conceptually illustrating an example of a wireless communication network, in accordance with various aspects of the present disclosure.

FIG. 2 is a block diagram conceptually illustrating an example of a base station in communication with a user equipment (UE) in a wireless communication network, in accordance with various aspects of the present disclosure.

FIG. 3A is a diagram illustrating an example of a wireless communication system that supports delivery of multicast services using a multicast radio bearer (MRB), in accordance with aspects of the present disclosure.

FIG. 3B illustrates an example of a wireless communication system that supports delivery of multicast services using an MRB, in accordance with aspects of the present disclosure.

FIG. 4 is a block diagram illustrating an example architecture for splitting radio link control (RLC) entities in an MRB, in accordance with aspects of the present disclosure.

FIGS. 5A and 5B are block diagrams illustrating examples of a transmitting packet data convergence protocol (PDCP) entity and a receiving PDCP entity, in accordance with aspects of the present disclosure.

FIG. 6A is a block diagram illustrating an example of a process for generating multiple data units from a single data unit, in accordance with aspects of the present disclosure.

FIG. 6B is a block diagram illustrating an example of a process for generating a single data unit from multiple data units, in accordance with aspects of the present disclosure.

FIG. 7 is a block diagram illustrating an example of a PDCP service data unit (SDU) level retransmission, in accordance with aspects of the present disclosure.

FIG. 8 is a block diagram illustrating an example of a network coding decoder, in accordance with aspects of the present disclosure.

FIG. 9 is a block diagram of a wireless communication device that receives an initial MBS transmission from a first path of an MRB and an MBS retransmission from a second path of the MRB, in accordance with aspects of the present disclosure.

FIG. 10 is a flow diagram illustrating an example process performed, for example, by a receiving device, in accordance with various aspects of the present disclosure.

FIG. 11 is a block diagram of a wireless communication device that transmits an initial IBS transmission from a first path of an MRB and an MBS retransmission from a second path of the MRB, in accordance with aspects of the present disclosure.

FIG. 12 is a flow diagram illustrating an example process performed, for example, by a transmitting device, in accordance with various aspects of the present disclosure.

### DETAILED DESCRIPTION

Various aspects of the disclosure are described more fully below with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method, which is practiced using other structure, functionality, or structure and functionality in addition to or other than the various aspects of the disclosure set forth. It should be understood that any aspect of the disclosure disclosed may be embodied by one or more elements of a claim.

Several aspects of telecommunications systems will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

It should be noted that while aspects may be described using terminology commonly associated with 5G and later wireless technologies, aspects of the present disclosure can be applied in other generation-based communications systems, such as and including 3G and/or 4G technologies.

A multicast and broadcast service (MBS) system is an example of a point-to-multipoint communication system where packets may be transmitted from a single source to multiple destinations. In some examples, the NBS system may broadcast packets to all receiving devices, such as user equipment (UEs), within an NBS zone. In other examples, the NBS system may multicast packets to a specific group of UEs selected from all UEs in the MBS zone. The MBS zone may be an example of a geographical area served by one or more base stations capable of MBS. The one or more base stations serving an MBS zone may transmit the same content to the UEs in the MBS zone. Some wireless communication systems, such as some NBS systems, support a retransmission of one or more packets to correct one or more errors of an initial transmission, such as a decoding error or another type of error.

In some systems, forward error correction (FEC) coding may be specified to transform an original message of k symbols into a longer message with n symbols, such that the original message may be recovered from a subset of the n symbols. A fountain code is an example of a type of FEC code. A system applying a fountain code may generate a potentially limitless sequence of encoded packets from a set of source packets. In such examples, the set of source packets may be recovered from any subset of the encoded packets when a quantity of encoded packets is greater than the quantity of source packets. Fountain codes may be considered rateless codes because a quantity of packets encoded based on the fountain code may be limitless. In some wireless systems, a fountain code may be referred to as a network code because the fountain code may be applied in a network layer. A Raptor code is an example of another type of network code.

Aspects of the present disclosure generally relate to splitting an initial transmission path and a retransmission path of a radio bearer. Various aspects more specifically relate to techniques and processes for applying a network coding function at one or both of the transmission path or the retransmission path of the radio bearer. In such aspects, the radio bearer may be an example of a multicast radio bearer (MRB). Additionally, a radio link control (RLC) entity of the transmission path and an RLC entity of the retransmission path may receive packets from a single packet data convergence protocol (PDCP) entity of the radio bearer. In particular examples, prior to receiving a transmission from either the transmission path or the retransmission path, a receiving device, such as a UE, may receive, from a network device, radio resource control (RRC) signaling including an initial transmission parameter and a retransmission parameter. In such examples, the initial transmission parameter indicates whether a network coding function is enabled for an initial transmission from the initial transmission path. Additionally, in such examples, the retransmission parameter indicates whether the network coding function is enabled for a retransmission from the retransmission parameter.

In various aspects, the initial transmission parameter indicates the network coding function is enabled for the initial transmission. In some examples, the PDCP entity may encode the set of initial data units based on applying the network coding function to a first set of source segments associated with a single data unit. An initial data unit in the set of initial data units may be an example of an encoded packet. In some examples, the UE may determine whether the set of initial data units satisfies a failure condition. In some such examples, the set of initial data units satisfies the failure condition based on a total quantity of the set of initial data units being less than a quantity threshold. In other such examples, the set of initial data units may satisfy the failure condition based on a failure to reconstruct a set of source segments. In various aspects, the UE may transmit, to the network device, a status data unit including a set of status indicators, one or more status indicators of the set of status indicators may indicate a reception failure based on the set of initial data units satisfying the failure condition.

In various aspects, the UE may receive a set of retransmission data units from the retransmission path of the network device based on one or more status indicators of the set of status indicators indicating the reception failure. In some examples, the retransmission parameter indicates the network coding function is enabled for the retransmission. In some examples, each retransmission data unit of the set of retransmission data units is a parity data unit, such as a parity PDCP SDU. In other examples, the set of retransmission data units may correspond to one or more source segments of the network device. In some other examples, the retransmission parameter indicates the network coding function is enabled for the retransmission and the initial transmission parameter indicates the network coding function is disabled for the initial transmission.

Particular implementations of the subject matter described in this disclosure may be implemented to realize one or more of the following potential advantages. In some examples, by splitting a radio bearer to include two paths—an initial transmission path and a retransmission path-some aspects of the present disclosure may reduce network overhead and reduce network latency by limiting retransmissions to UEs that transmitted a NACK based on an initial transmission. In some other examples, by applying network coding to one or both of initial transmissions or retransmissions, aspects of the present disclosure may improve the reliability of multicast transmissions, including one or both of the initial transmissions or the retransmissions.

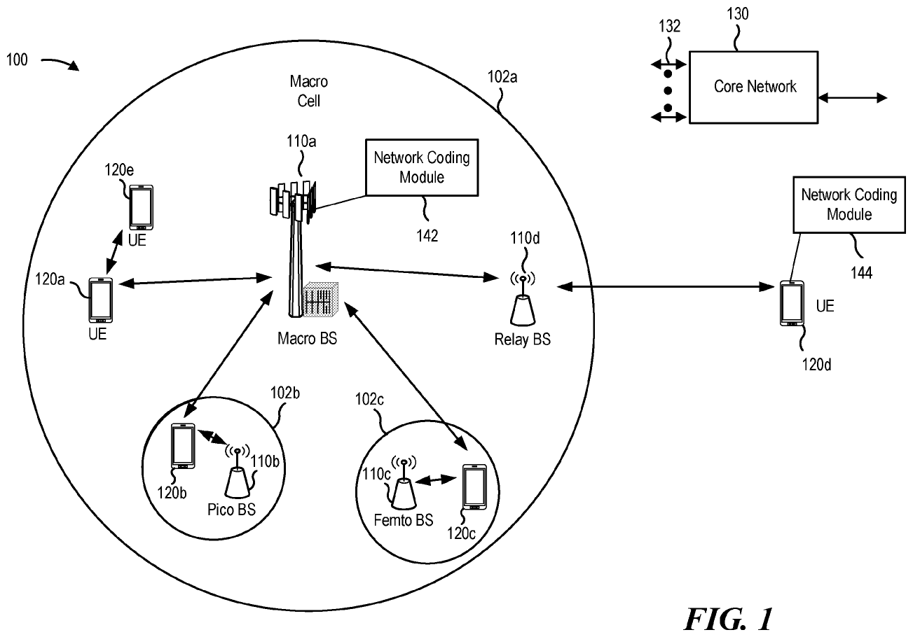

FIG. 1 is a block diagram illustrating a wireless network 100 in which aspects of the present disclosure may be practiced. The wireless network 100 may be a 5G or NR network or some other wireless network, such as an LTE network. The wireless network 100 may include a number of BSs 110 (shown as BS 110a, BS 110b, BS 110c, and BS 110d) and other network entities. A BS is an entity that communicates with user equipment (UEs) and may also be referred to as a base station, an NR BS, a Node B, a gNB, a 5G node B (NB), an access point, a transmit and receive point (TRP), and/or the like. Each BS may provide communications coverage for a particular geographic area. In 3GPP, the term “cell” can refer to a coverage area of a BS and/or a BS subsystem serving this coverage area, depending on the context in which the term is used.

A BS may provide communications coverage for a macro cell, a pico cell, a femto cell, and/or another type of cell. A macro cell may cover a relatively large geographic area (for example, several kilometers in radius) and may allow unrestricted access by UEs with service subscription. A pico cell may cover a relatively small geographic area and may allow unrestricted access by UEs with service subscription. A femto cell may cover a relatively small geographic area (for example, a home) and may allow restricted access by UEs having association with the femto cell (for example, UEs in a closed subscriber group (CSG)). A BS for a macro cell may be referred to as a macro BS. A BS for a pico cell may be referred to as a pico BS. A BS for a femto cell may be referred to as a femto BS or a home BS. In the example shown in FIG. 1, a BS 110a may be a macro BS for a macro cell 102a, a BS 110b may be a pico BS for a pico cell 102b, and a BS 110c may be a femto BS for a femto cell 102c. A BS may support one or multiple (for example, three) cells. The terms “eNB,” “base station,” “NR BS,” “gNB,” “TRP,” “AP,” “node B,” “5G NB,” and “cell” may be used interchangeably.

In some aspects, a cell may not necessarily be stationary, and the geographic area of the cell may move according to the location of a mobile BS. In some aspects, the BSs may be interconnected to one another and/or to one or more other BSs or network nodes (not shown) in the wireless network 100 through various types of backhaul interfaces such as a direct physical connection, a virtual network, and/or the like using any suitable transport network.

The wireless network 100 may also include relay stations. A relay station is an entity that can receive a transmission of data from an upstream station (for example, a BS or a UE) and send a transmission of the data to a downstream station (for example, a UE or a BS). A relay station may also be a UE that can relay transmissions for other UEs. In the example shown in FIG. 1, a relay station 110d may communicate with macro BS 110a and a UE 120d in order to facilitate communications between the BS 110a and UE 120d. A relay station may also be referred to as a relay BS, a relay base station, a relay, and/or the like.

The wireless network 100 may be a heterogeneous network that includes BSs of different types, for example, macro BSs, pico BSs, femto BSs, relay BSs, and/or the like. These different types of BSs may have different transmit power levels, different coverage areas, and different impact on interference in the wireless network 100. For example, macro BSs may have a high transmit power level (for example, 5 to 40 Watts) whereas pico BSs, femto BSs, and relay BSs may have lower transmit power levels (for example, 0.1 to 2 Watts).

As an example, the BSs 110 (shown as BS 110a, BS 110b, BS 110c, and BS 110d) and the core network 130 may exchange communications via backhaul links 132 (for example, S1, etc.). Base stations 110 may communicate with one another over other backhaul links (for example, X2, etc.) either directly or indirectly (for example, through core network 130).

The core network 130 may be an evolved packet core (EPC), which may include at least one mobility management entity (MME), at least one serving gateway (S-GW), and at least one packet data network (PDN) gateway (P-GW). The MME may be the control node that processes the signaling between the UEs 120 and the EPC. All user IP packets may be transferred through the S-GW, which itself may be connected to the P-GW. The P-GW may provide IP address allocation as well as other functions. The P-GW may be connected to the network operator's IP services. The operator's IP services may include the Internet, the Intranet, an IP multimedia subsystem (IMS), and a packet-switched (PS) streaming service.

The core network 130 may provide user authentication, access authorization, tracking, IP connectivity, and other access, routing, or mobility functions. One or more of the base stations 110 or access node controllers (ANCs) may interface with the core network 130 through backhaul links 132 (for example, S1, S2, etc.) and may perform radio configuration and scheduling for communications with the UEs 120. In some configurations, various functions of each access network entity or base station 110 may be distributed across various network devices (for example, radio heads and access network controllers) or consolidated into a single network device (for example, a base station 110).

UEs 120 (for example, 120a, 120b, and 120c) may be dispersed throughout the wireless network 100, and each UE may be stationary or mobile. A UE may also be referred to as an access terminal, a terminal, a mobile station, a subscriber unit, a station, and/or the like. A UE may be a cellular phone (for example, a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device or equipment, biometric sensors/devices, wearable devices (smart watches, smart clothing, smart glasses, smart wrist bands, smart jewelry (for example, smart ring, smart bracelet)), an entertainment device (for example, a music or video device, or a satellite radio), a vehicular component or sensor, smart meters/sensors, industrial manufacturing equipment, a global positioning system device, or any other suitable device that is configured to communicate via a wireless or wired medium.

One or more UEs 120 may establish a protocol data unit (PDU) session for a network slice. In some cases, the UE 120 may select a network slice based on an application or subscription service. By having different network slices serving different applications or subscriptions, the UE 120 may improve its resource utilization in the wireless network 100, while also satisfying performance specifications of individual applications of the UE 120. In some cases, the network slices used by UE 120 may be served by an AMF (not shown in FIG. 1) associated with one or both of the base station 110 or core network 130. In addition, session management of the network slices may be performed by an access and mobility management function (AMF).

The base station 110 may include a network coding module 142. For brevity, only one base station 110 is shown as including a network coding module 142. The network coding module 142 may transmit, to a UE 120, RRC signaling including an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. The network coding module 142 may also transmit, from the first RLC entity to the UE 120, a set of initial data units associated with the initial transmission. The network coding module 142 may further receive, from the UE 120, a status data unit including a set of status indicators. In some examples, each initial data unit of the set of initial data units corresponds to one or more status indicators of the set of status indicators. The network coding module 142 may also transmit, from the second RLC entity to the UE 120, a set of retransmission data units associated with the retransmission based on receiving the status data unit.

The UE 120 may include a network coding module 144. For brevity, only one UE 120 is shown as including a network coding module 144. In some examples, the network coding module 144 may receive, from a network device, such as a base station 110, RRC signaling including an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. The network coding module 144 may also receive, from the first RLC entity of the network device, the initial transmission comprising a set of initial data units. The network coding module 144 may further cause the UE 120 to transmit, to the network device, a status data unit comprising a set of status indicators based on the set of initial data units satisfying the failure condition. The network coding module 144 may still further receive, from the second RLC entity of the network device, the retransmission comprising a set of retransmission data units based on transmitting the status data unit. Finally, the network coding module 144 may generate one or more data units based on one or both of the set of retransmission data units or the set of initial data units.

Some UEs may be considered machine-type communications (MTC) or evolved or enhanced machine-type communications (eMTC) UEs. MTC and eMTC UEs include, for example, robots, drones, remote devices, sensors, meters, monitors, location tags, or the like, that may communicate with a base station, another device (for example, remote device), or some other entity. A wireless node may provide, for example, connectivity for or to a network (for example, a wide area network such as Internet or a cellular network) via a wired or wireless communications link. Some UEs may be considered Internet-of-Things (IoT) devices, or may be implemented as narrowband internet of things (NB-IoT) devices. Some UEs may be considered a customer premises equipment (CPE). UE 120 may be included inside a housing that houses components of UE 120, such as processor components, memory components, and/or the like.

In general, any number of wireless networks may be deployed in a given geographic area. Each wireless network may support a particular radio access technology (RAT) and may operate on one or more frequencies. A RAT may also be referred to as a radio technology, an air interface, and/or the like. A frequency may also be referred to as a carrier, a frequency channel, and/or the like. Each frequency may support a single RAT in a given geographic area in order to avoid interference between wireless networks of different RATs. In some cases, NR or 5G RAT networks may be deployed.

In some aspects, two or more UEs 120 (for example, shown as UE 120a and UE 120e) may communicate directly using one or more sidelink channels (for example, without using a base station 110 as an intermediary to communicate with one another). For example, the UEs 120 may communicate using peer-to-peer (P2P) communications, device-to-device (D2D) communications, a vehicle-to-everything (V2X) protocol (for example, which may include a vehicle-to-vehicle (V2V) protocol, a vehicle-to-infrastructure (V2I) protocol, and/or the like), a mesh network, and/or the like. In this case, the UE 120 may perform scheduling operations, resource selection operations, and/or other operations described elsewhere as being performed by the base station 110. For example, the base station 110 may configure a UE 120 via downlink control information (DCI), radio resource control (RRC) signaling, a media access control-control element (MAC-CE) or via system information (for example, a system information block (SIB).

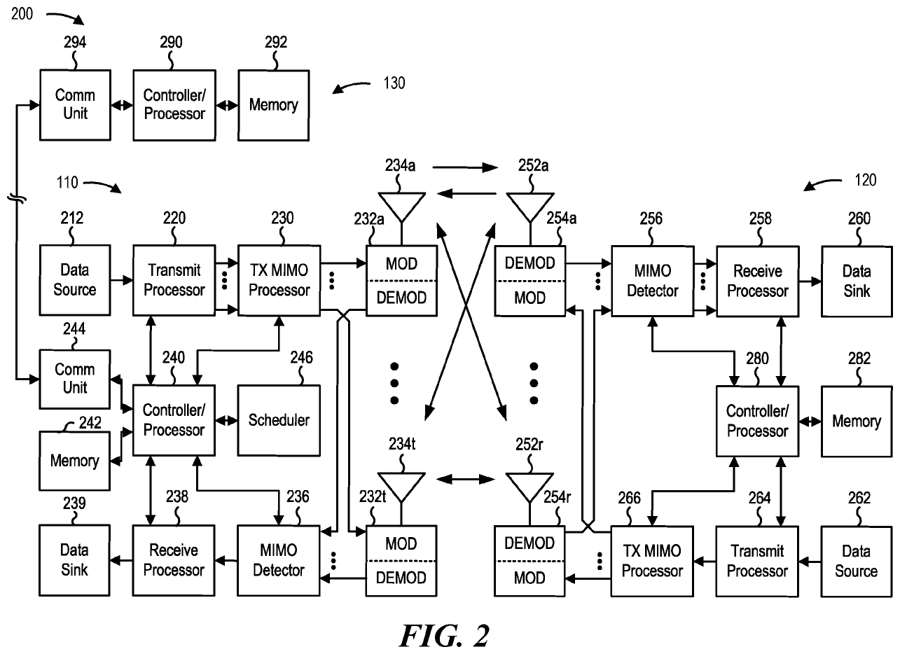

FIG. 2 is a block diagram of a design 200 of the base station 110 and UE 120, which may be one of the base stations and one of the UEs in FIG. 1. The base station 110 may be equipped with T antennas 234a through 234t, and UE 120 may be equipped with R antennas 252a through 252r, where in general T≥1 and R λ1.

At the base station 110, a transmit processor 220 may receive data from a data source 212 for one or more UEs, select one or more modulation and coding schemes (MCS) for each UE based at least in part on channel quality indicators (CQIs) received from the UE, process (for example, encode and modulate) the data for each UE based at least in part on the MCS(s) selected for the UE, and provide data symbols for all UEs. Decreasing the MCS lowers throughput but increases reliability of the transmission. The transmit processor 220 may also process system information (for example, for semi-static resource partitioning information (SRPI) and/or the like) and control information (for example, CQI requests, grants, upper layer signaling, and/or the like) and provide overhead symbols and control symbols. The transmit processor 220 may also generate reference symbols for reference signals (for example, the cell-specific reference signal (CRS)) and synchronization signals (for example, the primary synchronization signal (PSS) and secondary synchronization signal (SSS)). A transmit (TX) multiple-input multiple-output (MIMO) processor 230 may perform spatial processing (for example, precoding) on the data symbols, the control symbols, the overhead symbols, and/or the reference symbols, if applicable, and may provide T output symbol streams to T modulators (MODs) 232a through 232t. Each modulator 232 may process a respective output symbol stream (for example, for OFDM and/or the like) to obtain an output sample stream. Each modulator 232 may further process (for example, convert to analog, amplify, filter, and upconvert) the output sample stream to obtain a downlink signal. T downlink signals from modulators 232a through 232t may be transmitted via T antennas 234a through 234t, respectively. According to various aspects described in more detail below, the synchronization signals can be generated with location encoding to convey additional information.

At the UE 120, antennas 252a through 252r may receive the downlink signals from the base station 110 and/or other base stations and may provide received signals to demodulators (DEMODs) 254a through 254r, respectively. Each demodulator 254 may condition (for example, filter, amplify, downconvert, and digitize) a received signal to obtain input samples. Each demodulator 254 may further process the input samples (for example, for OFDM and/or the like) to obtain received symbols. A MIMO detector 256 may obtain received symbols from all R demodulators 254a through 254r, perform MIMO detection on the received symbols if applicable, and provide detected symbols. A receive processor 258 may process (for example, demodulate and decode) the detected symbols, provide decoded data for the UE 120 to a data sink 260, and provide decoded control information and system information to a controller/processor 280. A channel processor may determine reference signal received power (RSRP), received signal strength indicator (RSSI), reference signal received quality (RSRQ), channel quality indicator (CQI), and/or the like. In some aspects, one or more components of the UE 120 may be included in a housing.

On the uplink, at the UE 120, a transmit processor 264 may receive and process data from a data source 262 and control information (for example, for reports comprising RSRP, RSSI, RSRQ, CQI, and/or the like) from the controller/processor 280. Transmit processor 264 may also generate reference symbols for one or more reference signals. The symbols from the transmit processor 264 may be precoded by a TX MIMO processor 266 if applicable, further processed by modulators 254a through 254r (for example, for DFT-s-OFDM, CP-OFDM, and/or the like), and transmitted to the base station 110. At the base station 110, the uplink signals from the UE 120 and other UEs may be received by the antennas 234, processed by the demodulators 254, detected by a MIMO detector 236 if applicable, and further processed by a receive processor 238 to obtain decoded data and control information sent by the UE 120. The receive processor 238 may provide the decoded data to a data sink 239 and the decoded control information to a controller/processor 240. The base station 110 may include communications unit 244 and communicate to the core network 130 via the communications unit 244. The core network 130 may include a communications unit 294, a controller/processor 290, and a memory 292.

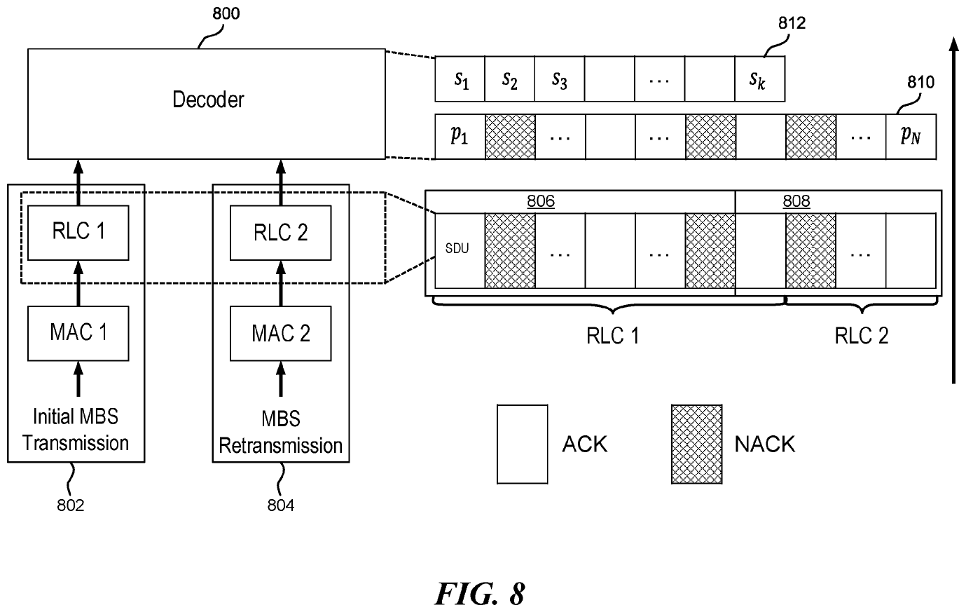

The controller/processor 240 of the base station 110, the controller/processor 280 of the UE 120, and/or any other component(s) of FIG. 2 may perform one or more techniques associated with transmitting an OAM beam via an OAM antenna including a number of concentric antenna array as described in more detail elsewhere. For example, the controller/processor 240 of the base station 110, the controller/processor 280 of the UE 120, and/or any other component(s) of FIG. 2 may perform or direct operations of, for example, the process of FIG. 8 or other processes as described. Memories 242 and 282 may store data and program codes for the base station 110 and UE 120, respectively. A scheduler 246 may schedule UEs for data transmission on the downlink and/or uplink.

A multicast and broadcast service (MBS) system may be an example of a point-to-multipoint communication system where packets may be transmitted from a single source to multiple destinations. In some examples, the MBS system may broadcast packets to all receiving devices, such as user equipment (UEs), within an MBS zone. In other examples, the MBS system may multicast packets to a specific group of UEs selected from all UEs in the MBS zone. The MBS zone may be an example of a geographical area served by one or more base stations capable of MBS. The one or more base stations serving an MBS zone may transmit the same content to the UEs in the MBS zone.

In some systems, forward error correction (FEC) coding may be specified to transform an original message of k symbols into a longer message with n symbols, such that the original message may be recovered from a subset of the n symbols. A fountain code is an example of a type of FEC code. A system applying a fountain code may generate a potentially limitless sequence of encoded packets from a set of source packets. In such examples, the set of source packets may be recovered from any subset of the encoded packets when a quantity of encoded packets is greater than the quantity of source packets. Fountain codes may be considered rateless codes because a quantity of packets encoded based on the fountain code may be limitless. In some wireless systems, a fountain code may be referred to as a network code because the fountain code may be applied in a network layer. A Raptor code is an example of a fountain code. Network coding may increase the reliability of transmissions, such as multicast transmissions, in an MBS system. Thus, it may be desirable to apply network coding to an MBS system.

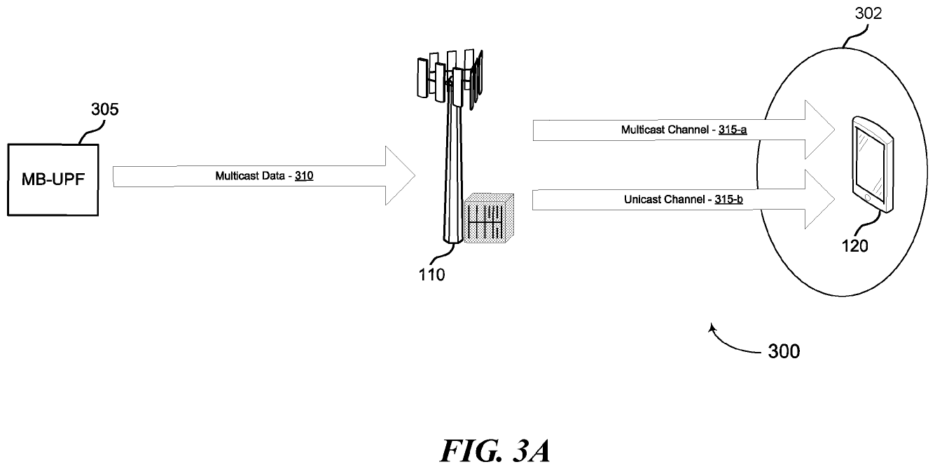

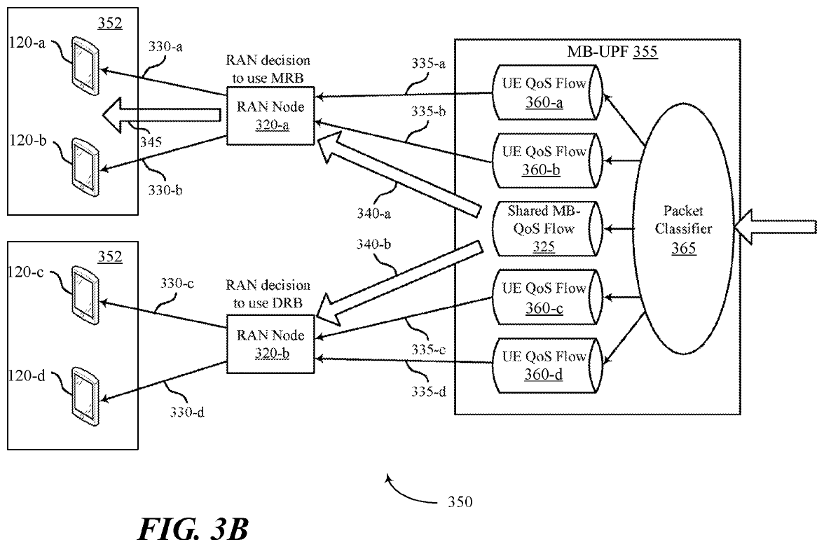

FIG. 3A is a diagram illustrating an example of a wireless communication system 300 that supports delivery of multicast services using a multicast radio bearer (MRB), in accordance with aspects of the present disclosure. In some examples, the wireless communication system 300 may implement aspects of the wireless network 100, as described with respect to FIG. 1. The wireless communication system 300 includes a base station 110 and a UE 120, which may be examples of the base station 110 and the UE 120 as described with reference to FIGS. 1 and 2. The wireless communication system 300 further includes a multicast broadcast-user plane function (MB-UPF) 305. The MB-UPF 305 may be a component of a core network, such as the core network 130 described with respect to FIG. 1. The core network (not shown in FIG. 3) may provide packet classification, aggregation, forwarding, routing, policy enforcement, and data buffering functionality, as well as other functions.

The MB-UPF 305 may provide multicast quality of service (QoS) flow indications to the base station 110 to transmit multicast data 310 to one or more UEs 120 in an MBS zone 302 during a multicast protocol data unit (PDU) session. For ease of explanation, FIG. 3 only illustrates one UE 120 in the MBS zone 302. In some examples, multiple UEs 120 may be located in the MBS zone 302. In some examples, the base station 110 may select a radio bearer for delivery of the multicast data 310 to the one or more UEs 120. The radio bearers may include an MRB and a data radio bearer (DRB). In some such examples, the base station may select the radio bearer based on an indication received from the MB-UPF 305. In one such example, the indication may identify a multicast data QoS flow, which may be associated with a QoS level.

In some implementations, the base station 110 (for example, RAN) selects the MRB or DRB based on a mapping of the multicast data 310 to the multicast data QoS flow. For example, the base station 110 may select the MRB for transmission of the multicast data 310 in response to identifying a group of UEs 120 for the multicast data 310 and also based on multicast QoS flow characteristics. In this example, the base station 110 selects the MRB to transmit the multicast data 310 to the UE 120 via a multicast channel 315-a. In some other examples, the multicast data 310 may be broadcast to all UEs 120 in the MBS zone 302. In other examples, the base station 110 may determine that only one UE 120 or a subset of UEs 120 from a group of UEs 120 are to receive the multicast data 310, for example, some UEs 120 may not support receiving multicast data via MRB. In this example, the base station 110 selects the DRB for transmitting multicast data 310 to the UE 120 via a unicast channel 315-b.

In some implementations, for a mixed multicast and unicast delivery mode, from the core network (for example, MB-UPF 305) perspective, the UE 120 is expected to be in a connected mode, such as a 5G non-access stratum (NAS) connection management (CM)-CONNECTED mode, to receive downlink (DL) transmissions. From a radio perspective (for example, from the perspective of the base station 110), the UE 120 may need to be in a connected state, such as an RRC_CONNECTED state. In the RRC_CONNECTED state, the UE 120 may provide hybrid automatic repeat request (HARQ) feedback, PDCP feedback, and RLC status feedback. The feedback may be multicast feedback or unicast feedback. As described, the base station 110 may perform re-transmissions, such as L1 HARQ or L2 automatic repeat request (ARQ) re-transmissions, via the unicast channel 315-b or the multicast channel 315-a based on the feedback.

FIG. 3B illustrates an example of a wireless communication system 350 that supports delivery of multicast services using an MRB, in accordance with aspects of the present disclosure. In some examples, the wireless communication system 350 may implement aspects of the wireless network 100. The wireless communication system 350 includes RAN nodes 320 and UEs 120. The RAN nodes 320 may be examples of the base stations 110 as described with respect to FIGS. 1 and 2. The wireless communication system 350 further includes a MB-UPF 355, which may be an example of the MB-UPF 305 as described with respect to FIG. 3A.

In the example of FIG. 3B, the wireless communication system 350 may support a multicast broadcast-quality of service (MB-QoS) flow. In some examples, a protocol data unit (PDU) session may be established between each UE 120 and a respective RAN node 320-a and 320-b. Each PDU session may be UE specific (for example, each UE 120 receives a unique PDU session ID). A PDU session may include a UE specific unicast flow (shown as UE QoS flow 360-a, 360-b, 360-c, and 360-d) and an MB-QoS flow (shown as shared MB-QoS flow 325). The shared MB-QoS flow 325 may be shared with other UEs 120 in a same MBS zone 352.

In the example of FIG. 3B, an MB-UPF 355 includes a packet classifier 365 and receives traffic from upstream network components. The packet classifier 365 may determine an appropriate flow (for example, UE QoS flows 360 and/or shared MB-QoS flow 325) to utilize to deliver the traffic. The flow may be determined based on the QoS associated with the traffic, the intended recipient (for example, one of the UE QoS flow 360-a, 360-b, 360-c, and 360-d or the shared MB-QoS flow 325) of the traffic based on an analysis of the traffic.

Each UE QoS flow 360 and the shared MB-QoS flow 325 may be associated with a different communication tunnel. For example, each UE QoS flow 360 may be associated with a single unicast tunnel 335. Additionally, a different MB tunnel 340 may be specified between the MB-UPF 355 and each RAN 320-a and 320-b.

Furthermore, each tunnel 335-a, 335-b, 335-c, 335-d, 340-a, and 340-b may be associated with unique tunnel endpoint identifiers (TEIDs). The MB tunnels 340 may be examples of multicast broadcast-N3 (MB-N3) shared tunnels with shared TEIDs. In some examples, an MB-N3 shared tunnel 340 may be established between a RAN 320 and the MB-UPF 355 based on a request to serve MB traffic to one or more UEs 120.

In an example traffic pattern for the wireless communication system 350, the MB-UPF 355 may receive traffic intended for a first UE 120-a. The MB-UPF 355 may select a first UE QoS flow 360-a, which routes the traffic to a first RAN node 320-a using a first UE specific tunnel 335-a. The first RAN node 320-a may then deliver the traffic to the first UE 120-a, in accordance with a first DRB 330-a for the first UE 120-a. In another example traffic pattern, the MB-UPF 355 receives MB traffic and selects the shared MB-QoS flow 325 for the MB traffic. The MB-UPF 355 may establish a first MB tunnel 340-a (for example, MB-N3 tunnel) with the first RAN node 320-a to deliver the MB traffic to the first UE 120-a and a second UE 120-b. In some examples, the MB-UPF 355 may transmit, to the first RAN node 320-a, an indication to serve the MB traffic to the first and second UEs 120-a and 120-b. The first RAN Node 320-a may then select a radio bearer mode for delivery of the MB traffic to the first and second UEs 120-a and 120-b. The selected mode may be a multicast/broadcast only mode, a mixed multicast/broadcast and unicast mode, or a unicast mode. In some examples, the selected mode may be based on a QoS associated with the MB traffic and a connection state of each UE 120-a and 120-b. In the example of FIG. 3B, the first RAN node 320-a may use an MB only mode or a mixed MB and unicast mode and delivers the traffic to the first and second UEs 120-a and 120-b via an MRB 345. In some examples, the first RAN Node 320-a may use the MRB 345 based on the QoS level satisfying a QoS condition, such as an amount of traffic being less than a traffic threshold.

In another example, the MB-UPF 355 may receive MB traffic and selects the shared MB-QoS flow 325 for the MB traffic. In this example, MB-UPF 355 may establish a second MB tunnel 340-b (for example, MB-N3 tunnel) with a second RAN node 320-b for delivery of the MB traffic to a third UE 120-c and a fourth UE 120-d. In the example of FIG. 3B, the second RAN node 320-b may use a mixed MB and unicast mode or a unicast only mode. In this example, the QoS level associated with the MB traffic may be greater than a traffic threshold. Therefore, the second RAN node 320-b may transmit the MB traffic to the third and fourth UEs 120-c and UE 120-d using different DRBs 330-c and 330-d.

As described with reference to FIG. 3B, the wireless communication system 350 may switch between a DRB and an MRB. In some examples, an N2 interface may be used for signaling an MB-flow setup or an MB-flow modification from an access and mobility management function (AMF) (not shown in FIG. 3B) to a RAN node 320. In some examples, a RAN node 320 may use a group radio network temporary identifier (G-RNTI) to perform an MB transmission.

Some MBS systems, such as LTE MBS systems, do not support MB retransmissions from a base station. Other MBS systems, such as NR MBS systems, may support MB retransmissions from a base station to increase reliability and reduce latency. In some systems, such as unicast communication systems, a radio link control (RLC) acknowledge mode (AM) may be specified for correcting residual errors in lower layers. In such systems, a transmitting device, such as a base station, may receive an acknowledgement (ACK) or a negative acknowledgment (NACK) from a receiving device, such as a UE, based on transmitting data to the receiving device according to the RLC AM.

In some examples, a lower layer of a transmitter may receive RLC service data units (SDUs) from upper layers and may segment or concatenate the RLC SDUs to RLC protocol data units (PDUs), which have a predefined size. In such examples, the transmitter may assign a sequence number to each PDU. In some examples, a receiver may receive one or more RLC PDUs from a transmitter and may reassemble the RLC PDUs into SDUs based on the sequence numbers. As described, an RLC AM may be specified for transmissions from the transmitter. In such examples, the receiver may transmit an ACK for each RLC PDU satisfying a decoding condition. In other examples, the receiver may transmit an ACK for a sequence of RLC PDUs based on each RLC PDU in the sequence of RLC PDUs satisfying the decoding condition. In other such examples, the transmitter may transmit a subsequent RLC PDU or a subsequent sequence of RLC PDUs based on receiving the ACK from the receiver. In other examples, the receiver may transmit a NACK or may not transmit an ACK for each RLC PDU that fails to satisfy the decoding condition. In such examples, the transmitter may retransmit each RLC PDU that is not associated with an ACK. Lower level error correction schemes, such as HARQ, for RLC transmissions may increase overhead for data transmissions and reduce network efficiency. In some systems, RLC AM may improve efficiency of wireless communication systems by reducing a number of ACKs specified for RLC transmissions. In some examples, the number of ACKs may be reduced based on an implementation of one or more factors, such as timers or polling requests.

In some aspects of the present disclosure, in an MBS system, a retransmission PDU generated at an upper layer of an MRB may correct a residual error of one or more lower layers. In some such aspects, network coding may be applied to the upper layer of the MRB of the MBS system to improve the reliability of multicast transmissions.

In some wireless communication systems, one MRB path may be used for both an initial MBS transmission and an MBS retransmission. In some examples, different UEs may fail to decode different packets. As described, a UE may transmit a NACK based on a failure to decode a packet. In such examples, the UE may receive the packet corresponding to the NACK from the MRB (for example, the MRB of the base station). However, this packet may not be desired by all UEs in an MBS zone. Therefore, transmitting the packet corresponding to NACK to all UEs in the MBS zone may increase network bandwidth and increase latency. Aspects of the present disclosure are directed to defining two different RLC entities for an MRB of an MBS system. In such aspects, a first RLC entity may be used for an initial MBS transmission and a second RLC entity may be used for an MBS retransmission.

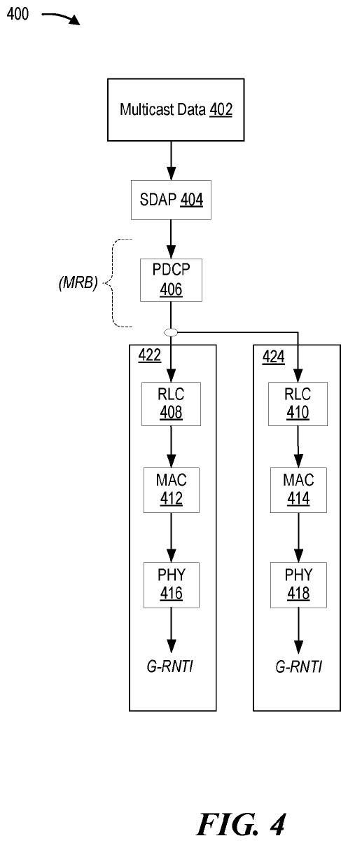

FIG. 4 is a block diagram illustrating an example architecture 400 for splitting RLC entities in an MRB, in accordance with aspects of the present disclosure. In FIG. 4, the architecture 400 includes multiple access stratum layers, such as a service data adaptation protocol (SDAP) layer, a PDCP layer, RLC layers, and MAC layers.

An SDAP entity 404 of the SDAP layer may map data, such as multicast data 402 or unicast data (not shown in FIG. 4), received from a core network (not shown in FIG. 4) to one of the radio bearers, such as an MRB or a DRB (not shown in FIG. 4) within a same PDU session. In some examples, the multicast data 402 (for example, multicast QoS flow data) may be received from a UPF (not shown in FIG. 4), such as an MB-UPF, for a multicast PDU session. In the example of FIG. 4, the SDAP entity 404 maps the multicast data to one of the radio bearers (for example, the MRB). For ease of explanation, only one radio bearer is shown in FIG. 4. Aspects of the present disclosure are not limited to one MRB, as shown in FIG. 4.

A PDCP entity 406 of the PDCP layer may perform various functions, such as robust header compression (RoHC) functions, security functions, and other functions. The PDCP entity 406 communicates with an RLC entity 408 or 410 via an RLC channel. In some implementations, as shown in FIG. 4, two different RLC entities 408 or 410 may be specified. Each RLC entity 408 and 410 may be associated with a different RLC path 422 and 424. In such implementations, a first RLC entity 408 may be specified for an initial MBS transmission and a second RLC entity 410 may be specified for an MBS retransmission. Each RLC entity 408 and 410 may segment PDU packets, reassemble segmented PDU packets, and perform ARQ error control procedures. Additionally, each RLC entity 408 and 410 may support different transmission modes, such as an unacknowledged mode (UM) and an acknowledged mode (AM). In some examples, data units, such as PDCP PDUs, for an initial MBS transmission routed to the first RLC path 422 may be scheduled for all UEs in an MBS zone. Additionally, as described, data units, such as PDCP PDUs, scheduled for an MBS retransmission may be routed to the second RLC path 424. In some examples, retransmissions from the second RLC path 424 may be scheduled for a subset of UEs from all UEs in an MBS zone. In some other examples, retransmissions from the second RLC path 424 may be scheduled for all UEs in the MBS zone. In such examples, UEs that did not send a NACK for an initial transmission corresponding to the retransmission may not process data received in the retransmission from the second RLC path 424.

In the example of FIG. 4, each MAC entity 412 and 414 may include a scheduler for scheduling and prioritizing packets received from an RLC layer entity 408 and 410 via a logical channel, such as a multicast broadcast traffic channel (MBTCH). In some examples, separate logical channels differentiate multicast data from unicast data. In some such examples, a physical layer (PHY) 416 and 418 may encode the multicast data 402 for transmission on a channel, such as a downlink shared channel. In some examples, the channel may be scrambled with a group radio network temporary identifier (G-RNTI).

In some implementations, a UE may receive an initial transmission parameter and a retransmission parameter via RRC signaling. In such implementations, the initial transmission parameter may indicate whether network coding is enabled for an initial MBS transmission and the retransmission parameter may indicate whether network coding is enabled for an MBS retransmission. Table 1 is an example of parameter indications and the corresponding network coding (NC), in accordance with aspects of the present disclosure.

TABLE 1

| NC RRC | | |
|---|---|---|
| Parameter | Initial Transmission | Retransmission |
| Option 0 | Network Coding Disabled | Network Coding Disabled |
| Option 1 | Network Coding Disabled | Network Coding Enabled |
| Option 2 | Network Coding Enabled | Network Coding Disabled |
| Option 3 | Network Coding Enabled | Network Coding Enabled |

As shown in Table 1, in some examples, the initial transmission parameter may indicate that network coding is disabled for the initial transmission from a first RLC entity and the retransmission parameter may indicate that network coding is disabled for a retransmission from a second RLC entity (for example, Option 0). In the current disclosure, a retransmission may be an example of an MBS retransmission and an initial transmission may be an example of an initial NBS transmission. In such examples, the MRB and the receiving device may process the initial transmission and the retransmission based on conventional techniques. In other examples, the initial transmission parameter may indicate that network coding is disabled for the initial transmission from the first RLC entity and the retransmission parameter may indicate that network coding is enabled for the retransmission from the second RLC entity (for example, Option 1). In such examples, the MRB and the receiving device may process the initial transmission based on conventional techniques. Additionally, in such examples, the MRB and the receiving device may process the retransmission based on one or more aspects of the present disclosure. In still other examples, the initial transmission parameter may indicate that network coding is enabled for the initial transmission from the first RLC entity and the retransmission parameter may indicate that network coding is disabled for the retransmission from the second RLC entity (for example, Option 2). In such examples, the MRB and the receiving device may process the initial transmission based on one or more aspects of the present disclosure. Additionally, in such examples, the MRB and the receiving device may process the retransmission based on conventional techniques, such as a NACKed PDCP SDU or PDU retransmission. In other examples, the initial transmission parameter may indicate that network coding is enabled for the initial transmission from the first RLC entity and the retransmission parameter may indicate that network coding is enabled for the retransmission from the second RLC entity (for example, Option 3). In such examples, the MRB and the receiving device may process both the initial transmission and the retransmission based on one or more aspects of the present disclosure.

In some implementations, a transmitter may apply a network coding function in a PDCP entity. In some examples, if network coding is enabled for only an initial MBS transmission or both the initial NBS transmission and an NBS retransmission, a single data unit, such as a PDCP SDU, may generate multiple data units, such as PDCP PDUs. In some other examples, if network coding is only enabled for the MBS retransmission or for both the initial NBS transmission and the NBS retransmission, the network coding may be applied to multiple source segments, such as different PDCP SDUs, to generate network coded data units, such as PDCP SDUs, for retransmission. In some other examples, if network coding is enabled in both the initial MBS transmission and the MBS retransmission, the network coding function may be applied to source packets from either a single data unit (for example, a single PDCP SDU) or different data units (for example, different PDCP SDUs) to generate one or more network coded data units, such as PDCP PDUs, for retransmission.

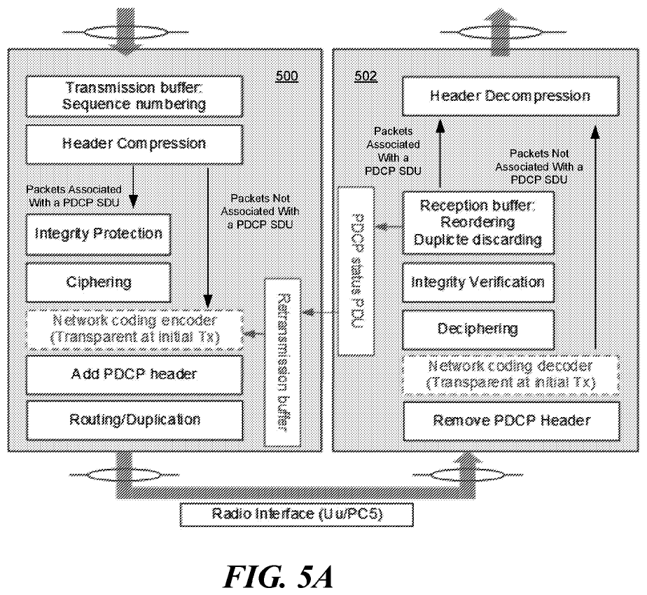

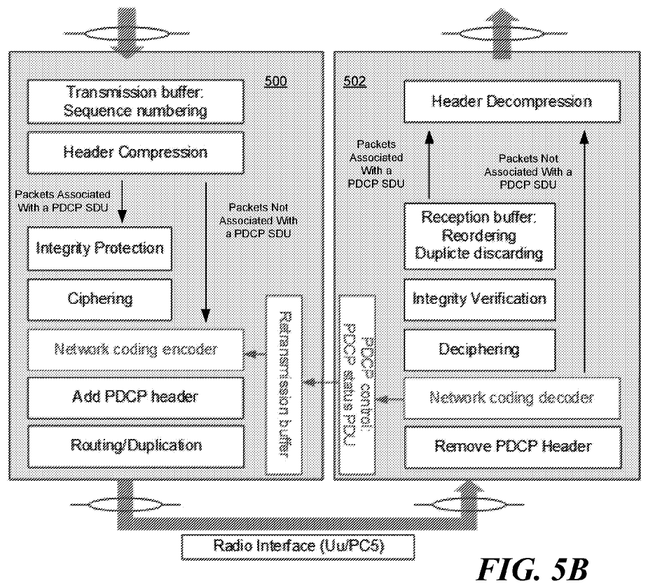

FIG. 5A is a block diagram illustrating an example of a transmitting PDCP entity 500 and a receiving PDCP entity 502, in accordance with aspects of the present disclosure. The transmitting PDCP entity 500 may be a component of a transmitting device, such as a first UE or a first base station. The receiving PDCP entity 502 may be a component of a receiving device, such as a second UE or a second base station. The first UE and the second UE may be examples of the HE 120 as described with reference to FIGS. 1 and 2. The first base station and the second base station may be examples of the base station 110 as described with reference to FIGS. 1 and 2. The transmitting PDCP entity 500 may be an example of the PDCP entity 406 as described with reference to FIG. 4. In the example of FIG. 5A, network coding is disabled for initial MBS transmissions.

In the example of FIG. 5A, the transmitting PDCP entity 500 may receive a data block, such as a PDCP SDU, from an upper layer entity, such as an SDAP entity 404 as described with reference to FIG. 4. As shown in FIG. 5A, the transmitting PDCP entity 500 may apply various functions to the received data block. In some examples, the transmitting PDCP entity 500 may temporarily store the data block in a transmission buffer and assign a sequence number to the data block. The data block may be associated with a user plane or a control plane. Additionally, as shown in FIG. 5A, the transmitting PDCP entity 500 may also compress a header of the data packet. In some examples, if the data packet is associated with a PDCP SDU, the transmitting PDCP entity 500 may perform a security procedure by applying an integrity protection function and a ciphering function (for example, encryption function). The integrity protection function and a ciphering function may be based on a sequence number associated with the data block.

In the example of FIG. 5A, the transmitting PDCP entity 500 may include a network coding function for encoding the data packet. Additionally, the transmitting PDCP entity 500 may include a retransmission buffer. In the example of FIG. 5A, the network coding function is bypassed based on the network coding being disabled for an initial MBS transmission. In such examples, a PDCP header may be added to the data packet and the data packet may be duplicated and routed to the receiving PDCP entity 502. In some other examples, if the data packet is not associated with a PDCP SDU, the PDCP header may be added to an output of the header compression function.

In some examples, the data packet may be transmitted to the receiving PDCP entity 502 on a radio interface (for example, a Uu interface or a PC5 interface). In such examples, the receiving PDCP entity 502 may receive the data packet on the radio interface and may remove the PDCP header of the received data packet. As shown in FIG. 5A, the receiving PDCP entity 502 may include a network coding decoder. In the example of FIG. 5A, the network coding decoder may be bypassed based on the network coding being disabled for an initial MBS transmission. In some examples, the receiving PDCP entity 502 may decipher the received data packet and apply an integrity verification function. The receiving PDCP entity 502 may also discard duplicate data packets, reorder data packets, and temporarily store the data packets in a reception buffer. In some examples, the receiving PDCP entity 502 may include a PDCP control function for generating one or more status packets, such as PDCP status PDUs, that indicate a status, such as a decoding status of the received data packet. The status packets may be transmitted to the transmitting PDCP entity 500 and stored in the retransmission buffer of the transmitting PDCP entity 500. The receiving PDCP entity 502 may also perform header decompression on the data packet and deliver a resulting data packet, such as a PDCP SDU, to an upper layer.

FIG. 5B is a block diagram illustrating an example of a transmitting PDCP entity 500 and a receiving PDCP entity 502, in accordance with aspects of the present disclosure. The transmitting PDCP entity 500 may be a component of a transmitting device, such as a first UE or a first base station. The receiving PDCP entity 502 may be a component of a receiving device, such as a second UE or a second base station. The first UE and the second UE may be examples of the UE 120, described with reference to FIGS. 1 and 2. The first base station and the second base station may be examples of the base station 110, described with reference to FIGS. 1 and 2. The transmitting PDCP entity 500 may be an example of the PDCP entity 406 as described with reference to FIG. 4. The transmitting PDCP entity 500 and the receiving PDCP entity 502 entity in the example of FIG. 5B perform the same functions as described with reference to Figure SA. However, in the example of FIG. 5B, networking coding is enabled for initial MBS transmissions. Therefore, in the example of FIG. 5B, the network coding encoder may be applied to a data packet at the transmitting PDCP entity 500 based on the network coding being enabled for the initial MBS transmissions. In such examples, the network coding encoder may generate multiple data packets based on a single data packet. As an example, the network coding encoder function may be applied to a PDCP SDU to generate multiple PDCP PDUs. In some examples, the PDCP header may be added to each data packet of the multiple data packets generated based on the network coding encoder function. Additionally, the multiple data packets (for example, PDUs) may be routed to may be routed to different RLC transmitting entities.

Additionally, in the example of FIG. 5B, the network coding decoder may be applied to the multiple data packets received at the receiving PDCP entity 502 based on the network coding being enabled for the initial MBS transmissions. In such examples, the network coding decoder may recover a single data packet from the multiple data packets. As an example, the network coding decoder function may be applied to multiple PDCP PDUs to recover a PDCP SDU.

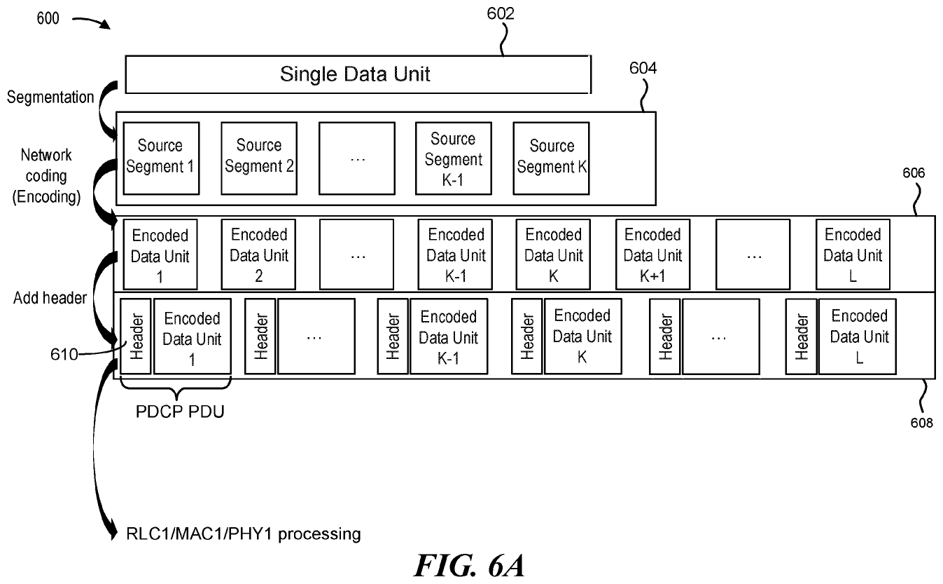

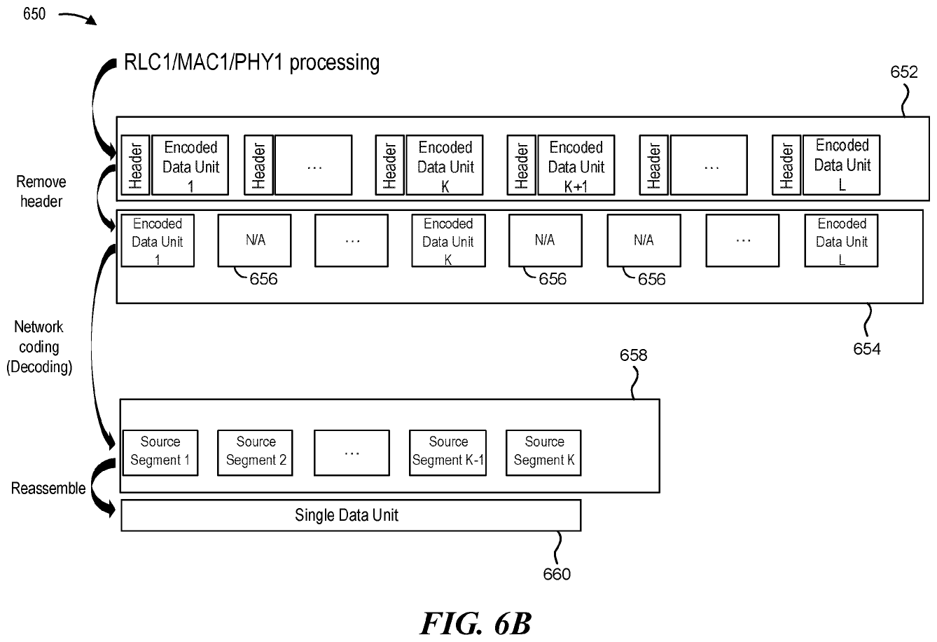

As described, a transmitting PDCP entity, such as the transmitting PDCP entity 500 of FIGS. 5A and 5B, may use a network coding function to generate multiple data packets, such as PDCP PDUs, from a single packet, such as a single PDCP SDU. FIG. 6A is a block diagram illustrating an example of a process 600 for generating multiple data packets from a single packet, in accordance with aspects of the present disclosure. The process 600 may be performed by one or more functions of a transmitting PDCP entity, such as the transmitting PDCP entity 500 described with reference to FIGS. 5A and 5B.

As shown in FIG. 6A, the process 600 may begin with a network coding encoder of the transmitting PDCP entity receiving a single data unit 602, such as a ciphered PDCP SDU. In the present disclosure, a data unit may be an example of a data packet. Additionally, the process 600 may segment (for example, divide) the single data unit 602 into K source segments 604 (1, . . . , K). Each source segment (for example, source packet) of the K source segments 604 may have a same number of bits as other source segments of the K source segments 604. In some examples, K may be determined based on a size of the single data unit 602 and a generator matrix. In the example of FIG. 6A, the process 600 applies a network coding function to the K source segments 604 to generate L encoded data units 606 (1, . . . , L). In some examples, the network coding function may be a fountain code, a Raptor code, a RaptorQ code, or another type of rateless code. As shown in the example of FIG. 6A, a quantity of L encoded data units 606 may be greater than a quantity of the K source segments 604. In some examples, the process 600 may add a header 610 to each encoded packet of the L encoded data units 606 to generate L data units 608 (for example, L PDCP PDUs). A data unit refers to an encoded data unit that includes a header 610. The header 610 of each data unit of the L data units 608 may include a sequence number (SN) of the single data unit 602. The SN may be associated with a count value of the single data unit 602. Additionally, the header 610 of each data unit of the L data units 608 may include a sub-SN indicating an index value. Each data unit of the L data units 608 may be associated with a different index value. As shown in FIG. 6A, the L data units 608 may be provided to lower layers, such as an RLC layer, a MAC layer, and a PHY layer for additional processing. The RLC layer, the MAC layer, and the PHY layer may be layers of an RLC path, such as the first RLC path 422 described with reference to FIG. 4, associated with an initial transmission.

FIG. 6B is a block diagram illustrating an example of a process 650 for generating a single data unit from multiple data units, in accordance with aspects of the present disclosure. The process 650 may be performed by one or more functions of a receiving PDCP entity, such as the receiving PDCP entity 502 described with reference to FIGS. 5A and 5B.

In the example of FIG. 6B, the process 650 may begin by receiving L data units 652 (1, . . . , L) from lower layers of a receiving device. In some examples, the lower layers may include a PHY layer, a MAC layer, and an RLC layer. The L data units 652 may be associated with an initial MBS transmission from a transmitting device. Additionally, in the example of FIG. 6B, the network coding is enabled for the initial MBS transmission. In some examples, the receiving device may receive an indication that the network coding is enabled for the initial MBS transmission. The indication may be an RRC parameter. The L data units 652 may be encoded based on a network coding function, such as a fountain coding function or a Raptor coding function, as described with reference to FIG. 6A.

As shown in FIG. 6B, after receiving the L data units 652 at the receiving PDCP entity, the process 650 may remove a header of each data unit (for example, encoded data unit) of the L data units 652. The process 650 may then determine a total quantity of N received data units 654 (shown as encoded data unit 1, . . . , encoded data unit L) based on removing the header of each encoded data unit of the L data units 652. As shown in FIG. 6B, the total quantity of N received data units 654 may be less than a total quantity of L data units 652 because a subset of one or more data units 656 of the L data units 652 may be unavailable due to an error, such as a communication error at one or both of the transmitting device or the receiving device. In some examples, a total quantity of the subset of one or more data units 656 of the L data units 652 may not be considered when determining the total quantity of the N received data units 654. In the example of FIG. 6B, the process 650 may identify a decoding error based on the total quantity of N received data units 654 being less than a total quantity of K source packets, such as the K source segments 604 described with reference to FIG. 6A, segmented from a single data unit, such as a PDCP SDU, at the transmitting PDCP entity.

In some examples, as shown in FIG. 6B, the process 650 decodes the N received data units 654 based on the networking coding function to generate a set of K source segments 658. The set of K source segments 658 (for example, source packets) may correspond to the K source segments, such as the K source segments 604 described with reference to FIG. 6A, of the transmitting PDCP entity segmented from the single data unit, such as the PDCP SDU. In some examples, the process 650 may fail to recover the set of K source segments 658 due to a decoding failure of the network coding function. In some other examples, the process 650 may reassemble a single data unit 660, such as a PDCP SDU, from the set of K source segments 658 based on successfully recovering (for example, successfully decoding) the set of K source segments 658. The single data unit 660 may be processed by upper layers of a protocol stack of the receiving device.

Different network coding functions, such as the fountain code, the Raptor code, or a RaptorQ code, may be associated with different estimated recovery failure probabilities. In some examples, an estimated probability of a recovery failure may be one hundred percent based on the total quantity of the N received data units 654 being less than a total quantity of K source packets. In other examples, the estimated probability of a recovery failure may be a function of the total quantity of the N received data units 654 and the total quantity of K source packets based on the total quantity of the N received data units 654 being greater than or equal to the total quantity of K source packets. In some such examples, the estimated probability of the recovery failure for the Raptor code may be determined as, 0.85×0.567^{N-K}, where a value of N is greater than or equal to a value of K, N represents the total quantity of received data units 654, and K represents the total quantity of K source packets. In some other such examples, the estimated probability of the recovery failure for the RaptorQ code may be determined as, ( 1/256)^{N-K+1}, where a value of N is greater than or equal to a value of K, N represents the total quantity of received data units 654, and K represents the total quantity of K source packets.

In the example of FIG. 6B, the process 650 may trigger a retransmission based on identifying a failure condition, such as a decoding failure. In some such examples, a status packet, such as a PDCP status PDU, may indicate the decoding failure. In such examples, the transmitting device may receive the status packet and initiate the NBS retransmission based on receiving the status packet. As described, the status packet, such as a PDCP status PDU, may be transmitted from the receiving device based on one or more data units satisfying a failure condition at the receiving PDCP entity. The status packet may include one or more parameters. In some examples, the status packet may include a header that indicates the packet is a status PDU. In some such examples, the status packet may also include one or more indications, including an indication of each initial data unit of the set of initial data units associated with a successful transmission (for example, an acknowledgment (ACK), an indication of each initial data unit missing from the set of initial data units (for example, a NACK), an indication of a quantity of additional data units needed by the UE to decode the set of initial data units (for example, Required_NumPDU), an indication of a total quantity of successfully decoded initial data units from the set of initial data units (for example, ACKed_NumPDU), an indication of each data unit of the set of initial data units that is missing a sub-sequence number (sub-SN) (for example, NACK_SubSN), or an indication of a rate adjustment command. The NACK and the ACK may be associated with an SN of a particular data unit. The rate adjustment command may adjust (for example, increase or decrease) a quantity of encoded data units, such as the L data units 606 of FIG. 6A, generated by the network coding encoder.

As shown in Table 1, in some examples, an RRC parameter (for example, initial transmission parameter) may indicate whether network coding is enabled for initial MBS transmissions and another RRC parameter (for example, retransmission parameter) may indicate whether network coding is enabled for MBS retransmissions. In some examples, the network coding may be disabled for both the initial MBS transmissions and the MBS retransmissions. In such examples, an MBS retransmission may be a conventional data unit retransmission, such as a conventional PDCP SDU retransmission. In some other examples, network coding may be disabled for the MBS retransmissions and enabled for the initial MBS transmissions. In some such examples, an MBS retransmission may be based on a data unit, such as a PDCP SDU, associated with a NACK. In other such examples, the MBS retransmission may be based on a data unit, such as PDCP PDU, associated with a NACK. In other examples, network coding may be disabled for the initial MBS transmissions and enabled for MBS retransmissions. In some such examples, the retransmission may be a PDCP SDU level retransmission where a network coded data unit, such as a PDCP SDU, for retransmission may be generated from different PDCP SDUs. In some other examples, the network coding may be enabled for both the initial MBS transmissions and the MBS retransmissions. In some such examples, the retransmission may be the PDCP SDU level retransmission where a network coded data unit, such as a PDCP SDU, for retransmission may be generated from different PDCP SDUs. In some other such examples, the retransmission may be a PDCP PDU level retransmission, where a network coded data unit, such as a PDCP PDU, for retransmission may be generated from source packets segmented from one data unit, such as a PDCP SDU, or multiple different data units.

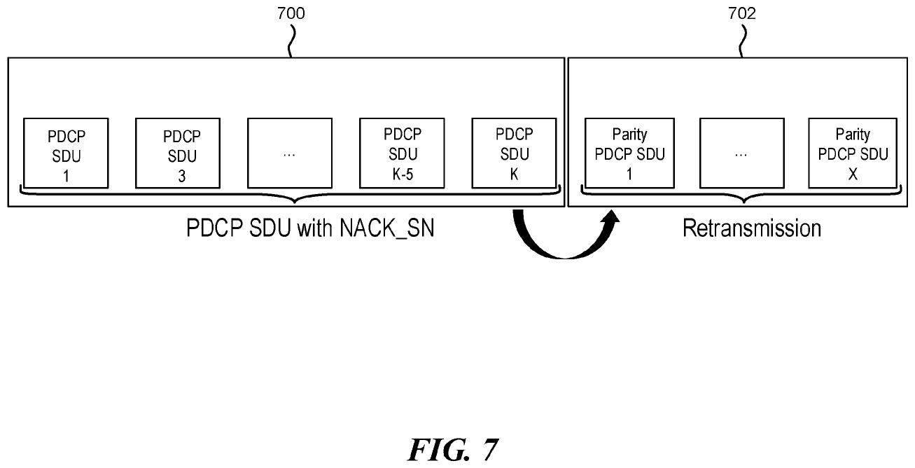

FIG. 7 is a block diagram illustrating an example of a PDCP SDU level retransmission, in accordance with aspects of the present disclosure. The PDCP SDU level retransmission of FIG. 7 may be performed based on network coding being enabled for only MBS retransmission (for example, Option 1 of Table 1) or network coding being enabled for both initial MBS transmissions and MBS retransmissions (for example, Option 3 of Table 1). As described, a transmitting PDCP entity, such as the transmitting PDCP entity 500 described with reference to FIGS. 5A and 5B, may receive a status packet from a receiving PDCP entity, such as the transmitting PDCP entity 500 described with reference to FIGS. 5A and 5B. In some examples, the status packet may indicate one or more data units, such as PDCP SDUs, associated with a NACK SN. In such examples, as shown in FIG. 7, a network coding encoder of the transmitting PDCP entity may consider each data unit, such as a PDCP SDU, associated with the NACK SN as a source packet (for example, a source segment). In the example of FIG. 7, each data unit of a set of K data units 700 (1, . . . , K) may be associated with a NACK SN. In this example, the network coding encoder may consider each data unit of the K data units 700 as a source packet. Additionally, the network coding encoder may generate each parity data unit of a set of parity data units 702 from one or more data units of the K data units 700 based on a network coding function. The set of parity data units 702 may be used for the MBS retransmission from the transmitting device. In some examples, a receiving PDCP entity may recover each data unit associated with a NACK based on one or more parity data units of the set of parity data units 702 and one or more data units associated with an ACK from an initial MBS transmission.

As described, in some examples, the MBS retransmission may be a PDCP PDU level retransmission. In such examples, a network coded data unit, such as a PDCP PDU, may be generated from source packets segmented from one data unit, such as a PDCP SDU, or multiple different data units. The network coded data unit may be retransmitted to the receiving device. In such examples, the network coded data unit may be generated based on the process 600 described with reference to FIG. 6A. Still, in such examples, the network coding function may generate X additional encoded data units (L+1, . . . , L+X) based on the K source segments 604. A quantity of X additional encoded data units generated for an initial transmission data unit, such as a PDCP SDU, associated with a NACK SN may be based on a parameter of the status packet (for example, status PDU). In some examples, the quantity of X additional encoded data units may be based on a required number parameter, such as the Required_NumPDU parameter, of the status packet that indicates a quantity of encoded data units needed at the receiving PDCP entity to recover the data unit of the initial MBS transmission that is associated with the NACK SN. In some examples, the X additional encoded data units may be generated from source segments, such as the K source segments 604, from a single data unit, such as the single data unit 602. In some other examples, the X additional encoded data units may be generated from source packets from different data units, such as the single data unit 602 and one or more other data units (for example, PDCP SDUs). In some examples, a header, such as the header 610 of FIG. 6A, may be added to each encoded packet of the X additional encoded data units to generate X additional data units (for example, X PDCP PDUs). The X additional data units may be transmitted to the receiving device to recover a data unit of the initial MBS transmission associated with a NACK SN.

FIG. 8 is a block diagram illustrating an example of a network coding decoder 800, in accordance with aspects of the present disclosure. The network coding decoder 800 may be a component of a receiving PDCP entity, such as the receiving PDCP entity 502 described with reference to FIGS. 5A and 5B. As shown in the example of FIG. 8, the network coding decoder 800 may receive encoded packets, such as L data units 806 (for example, a set of initial data units) from an initial MBS transmission path 802, such as the first RLC path 422 of FIG. 4, and X data units 808 (for example, a set of retransmission data units) from an MBS retransmission path 804, such as the second RLC path 424 of FIG. 4. As shown in FIG. 8, one or more data units of the received data units 806 and 808 may be associated with a NACK (shown as a cross-stitch pattern), while other data units may be associated with an ACK. In some examples, the network coding decoder 800 may only be aware of a total quantity of encoded data units 806 and 808 received from both paths 802 and 804. In some such examples, the encoded data units 806 and 808 from both paths 802 and 804 that correspond to a same SN may be aggregated at the network coding decoder 800 to form a set of data units 810 (p₁, . . . , pₙ). In the example of FIG. 8, a set of source segments 812 (s₁, . . . , sₙ) may be generated from the set of data units 810.

In some examples, the status packet, such as the PDCP status PDU, may be periodically transmitted or aperiodically transmitted. In some such examples, transmission of the status packet may be triggered based on an expiration of a periodic timer. In such examples, the transmitting device may configure the periodic timer via an indication transmitted in an RRC message or other types of signalling. In some other examples, an aperiodic transmission of the status packet may be triggered by a message transmitted from the transmitting PDCP entity.

In some examples, an MBS retransmission may be scheduled for a subset of UEs of all UEs in an MBS zone. As an example, one or more data units associated with an SN may only be scheduled for an MBS retransmission to UEs that transmitted a NACK SN corresponding to the SN of the one or more data units. In some other examples, the MBS retransmission may be scheduled for a subset of UEs of all UEs in an MBS zone. In some such examples, a UE may not process one or more data units associated with an SN in the MBS retransmission if the UE did not transmit a NACK SN corresponding to the SN of the one or more data units.

In some examples, two different pointers may be specified in the transmitting PDCP entity. A first pointer may be specified for the initial MBS transmission and a second pointer may be specified for the MBS retransmission. The first pointer may be incremented from a first data unit, such as a PDCP SDU, to a second data unit in a series of data units after the transmitting encoded packets associated with the first data unit. The first pointer may be incremented after an initial MBS transmission corresponding to a particular data unit. The second pointer may be incremented after an MBS retransmission corresponding to a particular data unit. Additionally, or alternatively, the second point may be incremented based on receiving an ACK (for example, ACK_SN) indicating successful receipt of the particular data unit. In some examples, the particular data unit may be discarded in the transmitting PDCP entity after both the first pointer and the second pointer are incremented to data units with SNs greater than an SN of the particular data unit.

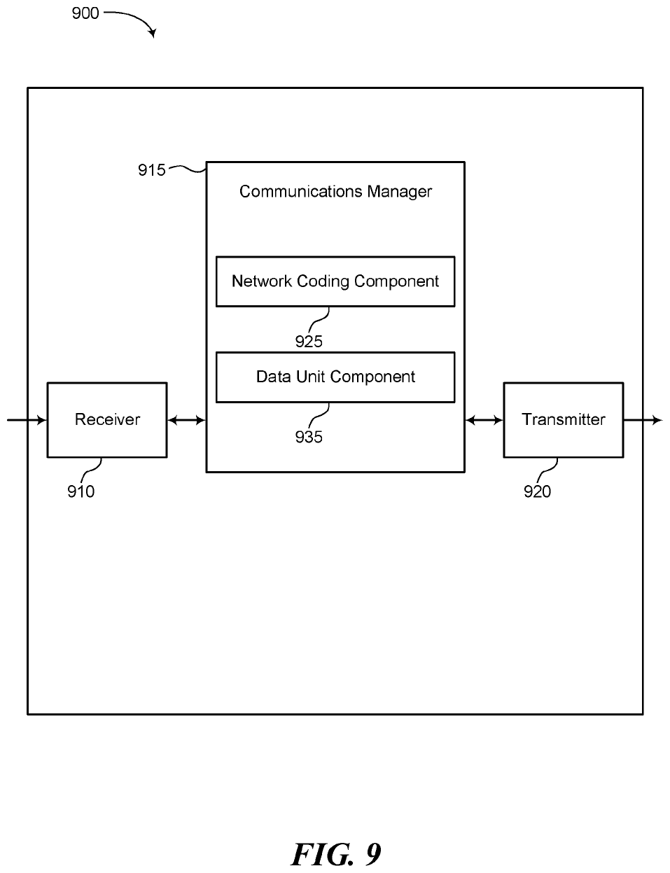

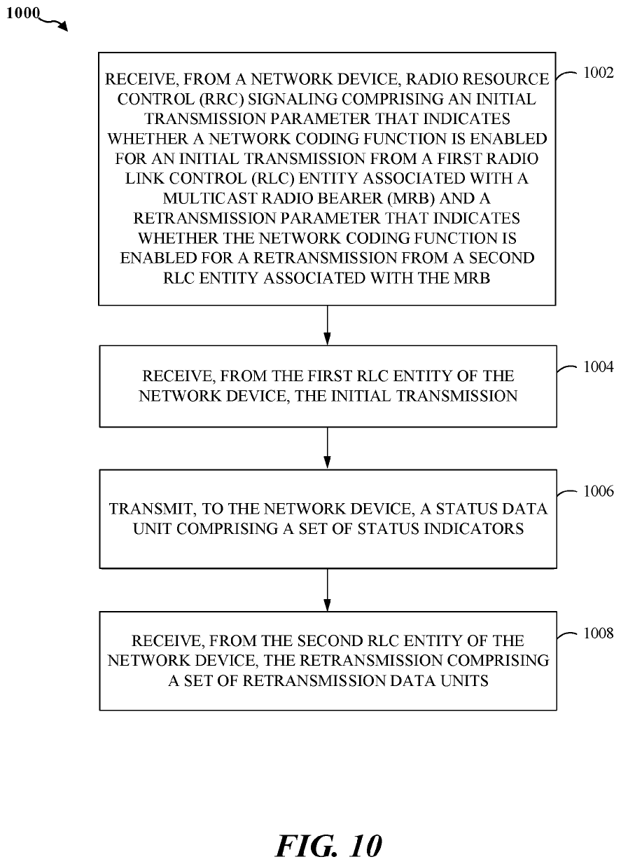

FIG. 9 shows a block diagram of a wireless communication device 900 that receives an initial MBS transmission from a first path of an MRB and an MBS retransmission from a second path of the MRB, in accordance with aspects of the present disclosure. The wireless communication device 900 may be an example of aspects of a UE 120, described with reference to FIGS. 1 and 2. The wireless communication device 900 may include a receiver 910, a communications manager 915, and a transmitter 920, which may be in communication with one another (for example, via one or more buses). In some implementations, the receiver 910 and the transmitter 920 may operate in conjunction with the OAM antenna 990. In some examples, the wireless communication device 900 is configured to perform operations, including operations of the process 1000 described below with reference to FIG. 10.

In some examples, the wireless communication device 900 can include a chip, system on chip (SoC), chipset, package, or device that includes at least one processor and at least one modem (for example, a 5G modem or other cellular modem). In some examples, the communications manager 915, or its sub-components, may be separate and distinct components. In some examples, at least some components of the communications manager 915 are implemented at least in part as software stored in a memory. For example, portions of one or more of the components of the communications manager 915 can be implemented as non-transitory code executable by the processor to perform the functions or operations of the respective component.

The receiver 910 may receive one or more reference signals (for example, periodically configured CSI-RSs, aperiodically configured CSI-RSs, or multi-beam-specific reference signals), synchronization signals (for example, synchronization signal blocks (SSBs)), control information, and/or data information, such as in the form of packets, from one or more other wireless communication devices via various channels including control channels (for example, a physical downlink control channel (PDCCH) and data channels (for example, a physical downlink shared channel (PDSCH)). The other wireless communication devices may include, but are not limited to, another UE 120 or a base station 110, described with reference to FIGS. 1 and 2.

The received information may be passed on to other components of the wireless communication device 900. The receiver 910 may be an example of aspects of the receive processor 258 described with reference to FIG. 2. The receiver 910 may include a set of radio frequency (RF) chains that are coupled with or otherwise utilize a set of antennas (for example, the set of antennas may be an example of aspects of the antennas 252a through 252r described with reference to FIG. 2).

The transmitter 920 may transmit signals generated by the communications manager 915 or other components of the wireless communication device 900. In some examples, the transmitter 920 may be collocated with the receiver 910 in a transceiver. The transmitter 920 may be an example of aspects of the transmit processor 264 described with reference to FIG. 2. The transmitter 920 may be coupled with or otherwise utilize a set of antennas (for example, the set of antennas may be an example of aspects of the antennas 252a through 252r described with reference to FIG. 2), which may be antenna elements shared with the receiver 910. In some examples, the transmitter 920 is configured to transmit control information in a physical uplink control channel (PUCCH) and data in a physical uplink shared channel (PUSCH).

The communications manager 915 may be an example of aspects of the controller/processor 280 described with reference to FIG. 2. The communications manager 915 includes a network coding component 925 and a data unit component 935. In some examples, working in conjunction with the receiver 910, the network coding component 925 may receive receiving, from a network device, RRC signaling comprising an initial transmission parameter that indicates whether a network coding function is enabled for an initial transmission from a first RLC entity associated with an MRB and a retransmission parameter that indicates whether the network coding function is enabled for a retransmission from a second RLC entity associated with the MRB. Additionally, working in conjunction with the receiver 910, the data unit component 935 receives, from the first RLC entity of the network device, the initial transmission. In some examples, the initial transmission includes a set of initial data units. In some such examples, working in conjunction with the transmitter 920, the data unit component 935 transmits, to the network device, a status data unit comprising a set of status indicators. In some examples, one or more status indicators of the set of status indicators indicate a reception failure based on the set of initial data units satisfying a failure condition. Furthermore, in some examples, working in conjunction with the receiver 910, the data unit component 935 receives, from the second RLC entity of the network device, the retransmission comprising a set of retransmission data units. In some examples, both the retransmission and the set of retransmission data units may be received based on one or more of the status indicators indicating the reception failure.

FIG. 10 is a flow diagram illustrating an example process 1000 performed, for example, by a receiving device, in accordance with various aspects of the present disclosure. The example process 1000 is an example of receiving an initial MBS transmission from a first path of an MRB and an MBS retransmission from a second path of the MRB, in accordance with aspects of the present disclosure. In some implementations, the process 1000 may be performed by a receiving device, such as the UE 120 described above with reference to FIGS. 1 and 2, and a receiving PDCP entity 502 described above with reference to FIGS. 5A and 5B, respectively.

In some implementations, the process 1000 begins in block 1002 with receiving, from a network device, RRC signaling comprising an initial transmission parameter that indicates whether a network coding function is enabled for an initial transmission from a first RLC entity associated with an MRB and a retransmission parameter that indicates whether the network coding function is enabled for a retransmission from a second RLC entity associated with the MRB. At block 1004, the process 1000 receives, from the first RLC entity of the network device, the initial transmission. In some examples, the initial transmission includes a set of initial data units. At block 1006, the process 1000 transmits, to the network device, a status data unit comprising a set of status indicators. In some examples, one or more status indicators of the set of status indicators indicate a reception failure based on the set of initial data units satisfying a failure condition. At block 1008, the process 1000 receives, from the second RLC entity of the network device, the retransmission comprising a set of retransmission data units. In some examples, both the retransmission and the set of retransmission data units may be received based on one or more of the status indicators indicating the reception failure.

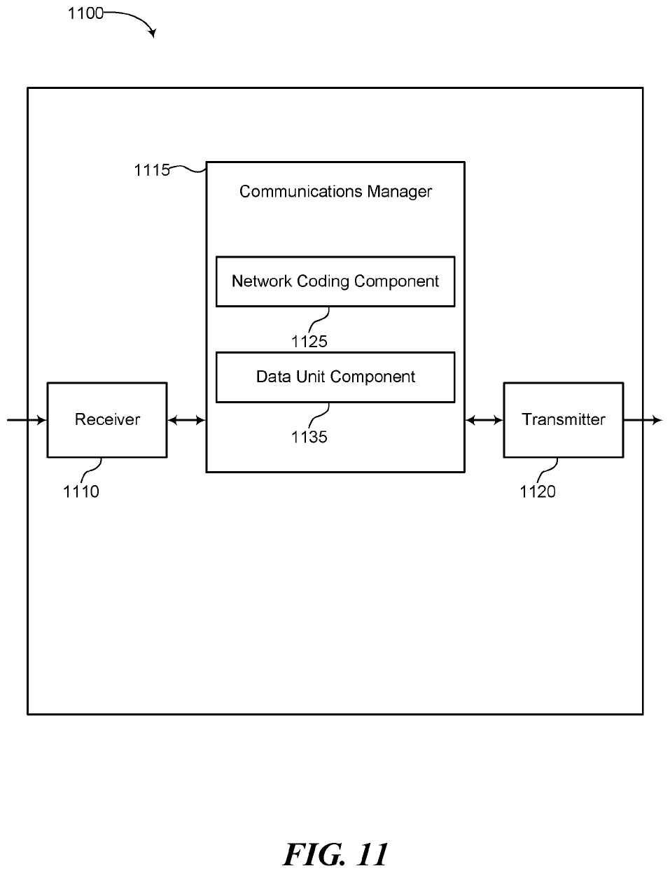

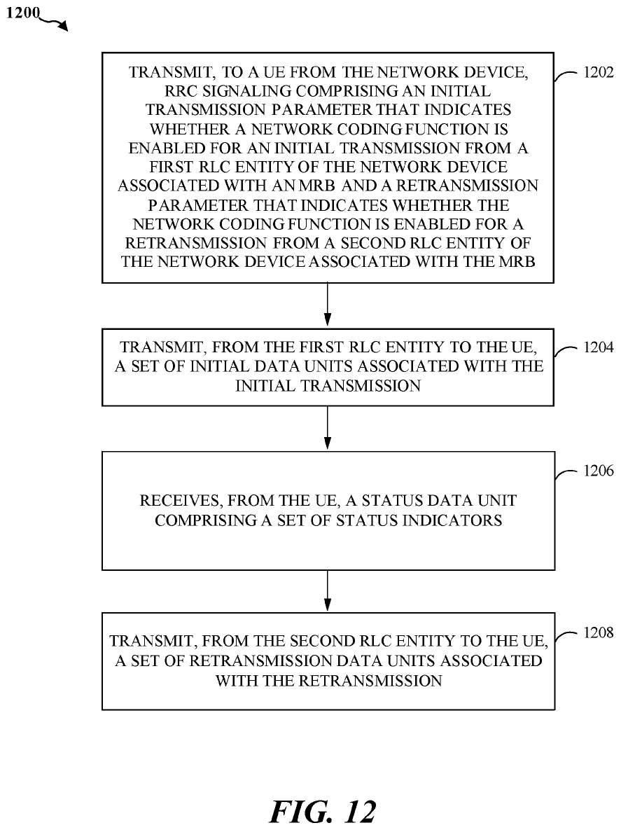

FIG. 11 shows a block diagram of a wireless communication device 1100 that transmitting an initial MBS transmission from a first path of an MRB and an MBS retransmission from a second path of the MRB, in accordance with aspects of the present disclosure. The wireless communication device 1100 may be an example of aspects of a base station 110, described with reference to FIGS. 1 and 2. The wireless communication device 1100 may include a receiver 1110, a communications manager 1115, and a transmitter 1120, which may be in communication with one another (for example, via one or more buses). In some examples, the wireless communication device 1100 is configured to perform operations, including operations of the process 1200 described below with reference to FIG. 12.

In some examples, the wireless communication device 1100 can include a chip, system on chip (SoC), chipset, package, or device that includes at least one processor and at least one modem (for example, a 5G modem or other cellular modem). In some examples, the communications manager 1115, or its sub-components, may be separate and distinct components. In some examples, at least some components of the communications manager 1115 are implemented at least in part as software stored in a memory. For example, portions of one or more of the components of the communications manager 1115 can be implemented as non-transitory code executable by the processor to perform the functions or operations of the respective component.

The receiver 1110 may receive one or more reference signals (for example, periodically configured CSI-RSs, aperiodically configured CSI-RSs, or multi-beam-specific reference signals), synchronization signals (for example, synchronization signal blocks (SSBs)), control information, and/or data information, such as in the form of packets, from one or more other wireless communication devices via various channels including control channels (for example, a PDCCH) and data channels (for example, a PDSCH). The other wireless communication devices may include, but are not limited to, another base station 110 or a UE 120, described with reference to FIGS. 1 and 2.

The received information may be passed on to other components of the wireless communication device 1100. The receiver 1110 may be an example of aspects of the receive processor 238 described with reference to FIG. 2. The receiver 1110 may include a set of radio frequency (RF) chains that are coupled with or otherwise utilize a set of antennas (for example, the set of antennas may be an example of aspects of the antennas 234a through 234t described with reference to FIG. 2).

The transmitter 1120 may transmit signals generated by the communications manager 1115 or other components of the wireless communication device 1100. In some examples, the transmitter 1120 may be collocated with the receiver 1110 in a transceiver. The transmitter 1120 may be an example of aspects of the transmit processor 220 described with reference to FIG. 2. The transmitter 1120 may be coupled with or otherwise utilize a set of antennas (for example, the set of antennas may be an example of aspects of the antennas 234a through 234t), which may be antenna elements shared with the receiver 1110. In some examples, the transmitter 1120 is configured to transmit control information in a physical uplink control channel (PUCCH) and data in a physical uplink shared channel (PUSCH).

The communications manager 1115 may be an example of aspects of the controller/processor 240 described with reference to FIG. 2. The communications manager 1115 includes a network coding component 1125 and a data unit component 1135. In some examples, working in conjunction with the transmitter 1120 the network coding component 1125 transmits, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. In some examples, working in conjunction with the transmitter 1120, the data unit component 1135 transmits, from the first RLC entity to the UE, a set of initial data units associated with the initial transmission. Additionally, working in conjunction with the receiver 1110, the data unit component 1135 receives, from the UE, a status data unit comprising a set of status indicators. In some examples, one or more status indicators of the set of status indicators indicate a reception failure. Furthermore, working in conjunction with the transmitter 1120, the data unit component 1135 transmits, from the second RLC entity to the UE, a set of retransmission data units associated with the retransmission. In some examples, the set of retransmission data units may be transmitted based on the one or more status indicators indicating the reception failure.

FIG. 12 is a flow diagram illustrating an example process 1200 performed, for example, by a receiving device, in accordance with various aspects of the present disclosure. The example process 1200 is an example of transmitting an initial MBS transmission from a first path of an MRB and an MBS retransmission from a second path of the MRB, in accordance with aspects of the present disclosure. In some implementations, the process 1200 may be performed by a receiving device, such as the base station described above with reference to FIGS. 1 and 2, and a transmitting PDCP entity 500 described above with reference to FIGS. 5A and 5B, respectively.

In some implementations, the process 1200 begins in block 1202 with transmitting, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB. At block 1204, the process 1200 transmits, from the first RLC entity to the UE, a set of initial data units associated with the initial transmission. At block 1206, the process 1200 receives, from the UE, a status data unit comprising a set of status indicators. In some examples, one or more status indicators of the set of status indicators indicate a reception failure. At block 1208, the process 1200 transmits, from the second RLC entity to the UE, a set of retransmission data units associated with the retransmission. In some examples, the set of retransmission data units may be transmitted based on the one or more status indicators indicating the reception failure.

The following provides an overview of some Aspects of the present disclosure:

Aspect 1. A method for wireless communication performed by a UE, comprising: receiving, from a network device, RRC signaling comprising an initial transmission parameter that indicates whether a network coding function is enabled for an initial transmission from a first RLC entity associated with an MRB and a retransmission parameter that indicates whether the network coding function is enabled for a retransmission from a second RLC entity associated with the MRB; receiving, from the first RLC entity of the network device, the initial transmission, the initial transmission comprising a set of initial data units; transmitting, to the network device, a status data unit comprising a set of status indicators, one or more status indicators of the set of status indicators indicate a reception failure based on the set of initial data units satisfying a failure condition; and receiving, from the second RLC entity of the network device, the retransmission comprising a set of retransmission data units, both the retransmission and the set of retransmission data units being received based on one or more of the status indicators indicating a reception failure.

Aspect 2. The method of Aspect 1, reconstructing one or more data units based on decoding and combining one or more retransmission data units of the set of retransmission data units and one or more initial data units of the set of initial data units.

Aspect 3. The method of any one of Aspects 1-2, wherein the set of status indicators comprise one or more of an indication of each initial data unit of the set of initial data units associated with a successful reception, an indication of each initial data unit missing from the set of initial data units, an indication of a quantity of additional data units needed by the UE to decode the set of initial data units, an indication of a total quantity of successfully decoded initial data units from the set of initial data units, an indication of each data unit of the set of initial data units that is missing a sub-sequence number (sub-SN), or an indication of a rate adjustment command.

Aspect 4. The method of Aspect 3, wherein a total quantity of the set of retransmission data units is based on the indication of the quantity of additional data units.

Aspect 5. The method of any one of Aspects 1-4, wherein: the initial transmission parameter indicates the network coding function is enabled for the initial transmission; the set of initial data units comprises two or more initial data units based on the network coding function being enabled for the initial transmission; and the method further comprises generating a generator matrix associated with the network coding function based on receiving the set of initial data units.

Aspect 6. The method of Aspect 5, further comprising determining a quantity threshold based on the generator matrix, wherein the set of initial data units satisfy the failure condition based on a total quantity of the set of initial data units being less than the quantity threshold.

Aspect 7. The method of Aspect 5, further comprising decoding the set of initial data units based on the generator matrix to reconstruct a set of source segments for generating the one or more data units, wherein the set of initial data units satisfy the failure condition based on a failure to reconstruct the set of source segments.

Aspect 8. The method of any one of Aspects 5-7, further comprising reconstructing one or more source segments of the set of source segments based on the set of retransmission data units and the set of initial data units, wherein: the retransmission parameter indicates the network coding function is enabled for the retransmission; and the set of retransmission data units comprises one or more retransmission data units based on the network coding function being enabled for the retransmission.

Aspect 9. The method of Aspect 8, wherein each retransmission data unit of the set of retransmission data units is a parity data unit.

Aspect 10. The method of Aspect 8, wherein the set of initial data units and the set of retransmission data units comprise a same sequence number associated with a count value.

Aspect 11. The method of Aspect 10, wherein the set of retransmission data units correspond to a set of source segments at the network device, each source segment of the set of source segments at the network device associated with a single source data unit.

Aspect 12. The method of Aspect 10, wherein the set of retransmission data units correspond to a set of source segments at the network device, each source segment of the set of source segments at the network device associated with a plurality of source data units.

Aspect 13. The method of any one of Aspects 1-3, wherein: the retransmission parameter indicates the network coding function is enabled for the retransmission and the initial transmission parameter indicates the network coding function is disabled for the initial transmission; the set of retransmission data units comprises one or more retransmission data units based on the network coding function being enabled for the retransmission; each retransmission data unit of the set of retransmission data units is a parity data unit; and the method further comprises reconstructing one or more source segments of a set of source segments.

Aspect 14. The method of any one of Aspects 1-13, wherein the status data unit is one status data unit of a plurality of status data units that are periodically transmitted based on a timer.

Aspect 15. The method of any one of Aspects 1-13, wherein the status data unit is one status data unit of a plurality of status data units, each status data unit of the plurality of status data units being aperiodically transmitted based on receiving a respective trigger from the MRB.

Aspect 16. A method for wireless communication performed by a network device, comprising: transmitting, to a UE from the network device, RRC signaling comprising an initial transmission parameter that indicates whether a network coding function is enabled for an initial transmission from a first RLC entity of the network device associated with an MRB and a retransmission parameter that indicates whether the network coding function is enabled for a retransmission from a second RLC entity of the network device associated with the MRB; transmitting, from the first RLC entity to the UE, a set of initial data units associated with the initial transmission; receiving, from the UE, a status data unit comprising a set of status indicators, one or more status indicators of the set of status indicators indicate a reception failure; and transmitting, from the second RLC entity to the UE, a set of retransmission data units associated with the retransmission, the set of retransmission data units being transmitted based on the one or more status indicators indicating the reception failure.

Aspect 17. The method of Aspect 16, wherein the set of status indicators comprise one or more of an indication of each initial data unit of the set of initial data units associated with a successful reception, an indication for each initial data unit missing from the set of initial data units, an indication of a quantity of additional data units needed by the UE to decode the set of initial data units, an indication of a total quantity of successfully decoded initial data units from the set of initial data units, an indication of each initial data unit of the set of initial data units that is missing a sub-sequence number, or an indication of a rate adjustment command.

Aspect 18. The method of Aspect 17, wherein a total quantity of the set of retransmission data units is based on the indication of the quantity of additional data units.

Aspect 19. The method of any one of Aspects 16-18, wherein: the RRC signaling indicates the network coding function is enabled for the initial transmission; and the set of initial data units comprises two or more initial data units based on the network coding function being enabled for the initial transmission.

Aspect 20. The method of Aspect 19, further comprising: segmenting, at a packet data convergence protocol (PDCP) entity of the network device, a source data unit; and encoding, at the PDCP entity of the network device, the set of initial data units based on applying the network coding function to a first set of source segments associated with the source data unit, wherein: each initial data unit of the set of initial data units comprises a sequence number associated with the source data unit and a different respective sub-sequence number of a plurality of sub-sequence numbers; and a total quantity of sub-sequence numbers is equal to a total quantity of the set of initial data units.

Aspect 21. The method of Aspect 20, wherein a total quantity of the first set of source segments is less than the total quantity of the set of initial data units.

Aspect 22. The method of Aspect 20, wherein: the RRC signaling indicates the network coding function is enabled for the retransmission; and the set of retransmission data units comprises one or more retransmission data units based on the network coding function being enabled for the retransmission.

Aspect 23. The method of Aspect 22, further comprising constructing, at the PDCP entity, a set of parity data units from one or more source segments of the first set of source segments, wherein: each source segment of the one or more source segments corresponding to a negative acknowledgement associated with a different respective status indicator of the set of status indicators; and each retransmission data unit of the set of retransmission data units is a different respective parity data unit of the set of parity data units.

Aspect 24. The method of Aspect 23, further comprising: segmenting, at the PDCP entity, one or more source data units; and encoding, at the PDCP entity, the set of retransmission units based on applying the network coding function to a second set of source segments associated with the one or more source data units.

Aspect 25. The method of Aspect 19, further comprising constructing, at a packet data convergence protocol (PDCP) entity of the network device, a set of parity data units from one or more source segments of a set of source segments, wherein: the RRC signaling indicates the network coding function is enabled for the retransmission and the network coding function is disabled for the initial transmission; the set of retransmission data units comprises one or more retransmission data units based on the network coding function being enabled for the retransmission; each source segment of the set of source segments corresponding to a negative acknowledgement associated with a different respective status indicator of the set of status indicators; and each retransmission data unit of the set of retransmission data units is a different respective parity data unit of the set of parity data units.

Aspect 26. The method of any one of Aspects 16-25, further comprising: transmitting, to the UE, a configuration for a periodic feedback timer; and receiving the status data unit based on an expiration of the periodic feedback timer.

Aspect 27. The method of any one of Aspects 16-25, further comprising: transmitting, to the UE, a signal to trigger a transmission of the status data unit; and receiving, from the UE, the status data unit based on transmitting the trigger.

Aspect 28. The method of any one of Aspects 16-27, further comprising scheduling the retransmission regardless of receiving the status data unit.

The foregoing disclosure provides illustration and description, but is not intended to be exhaustive or to limit the aspects to the precise form disclosed. Modifications and variations may be made in light of the above disclosure or may be acquired from practice of the aspects.

As used, the term “component” is intended to be broadly construed as hardware, firmware, and/or a combination of hardware and software. As used, a processor is implemented in hardware, firmware, and/or a combination of hardware and software.

Some aspects are described in connection with thresholds. As used, satisfying a threshold may, depending on the context, refer to a value being greater than the threshold, greater than or equal to the threshold, less than the threshold, less than or equal to the threshold, equal to the threshold, not equal to the threshold, and/or the like.

It will be apparent that systems and/or methods described may be implemented in different forms of hardware, firmware, and/or a combination of hardware and software. The actual specialized control hardware or software code used to implement these systems and/or methods is not limiting of the aspects. Thus, the operation and behavior of the systems and/or methods were described without reference to specific software code—it being understood that software and hardware can be designed to implement the systems and/or methods based, at least in part, on the description.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (for example, a-a, a-a-a, a-a-b, a-a-c, a-b-b, a-c-c, b-b, b-b-b, b-b-c, c-c, and c-c-c or any other ordering of a, b, and c).

No element, act, or instruction used should be construed as critical or essential unless explicitly described as such. Also, as used, the articles “a” and “an” are intended to include one or more items, and may be used interchangeably with “one or more.” Furthermore, as used, the terms “set” and “group” are intended to include one or more items (for example, related items, unrelated items, a combination of related and unrelated items, and/or the like), and may be used interchangeably with “one or more.” Where only one item is intended, the phrase “only one” or similar language is used. Also, as used, the terms “has,” “have,” “having,” and/or the like are intended to be open-ended terms. Further, the phrase “based on” is intended to mean “based, at least in part, on” unless explicitly stated otherwise.

What is claimed is:

1. A method for wireless communication performed by a user equipment (UE), comprising:
receiving, from a network device, radio resource control (RRC) signaling comprising an initial transmission parameter indicating whether a network coding function is enabled for an initial transmission from a first radio link control (RLC) entity associated with a multicast radio bearer (MRB) and a retransmission parameter indicating whether the network coding function is enabled for a retransmission from a second RLC entity associated with the MRB;
receiving, from the first RLC entity of the network device, the initial transmission, the initial transmission comprising a set of initial data units;
transmitting, to the network device, a status data unit comprising a set of status indicators, one or more status indicators of the set of status indicators indicating a reception failure based on the set of initial data units satisfying a failure condition; and
receiving, from the second RLC entity of the network device, the retransmission comprising a set of retransmission data units, both the retransmission and the set of retransmission data units being received based on the one or more status indicators indicating the reception failure.

2. The method of claim 1, reconstructing one or more data units based on decoding and combining one or more retransmission data units of the set of retransmission data units and one or more initial data units of the set of initial data units.

3. The method of claim 1, wherein the set of status indicators comprise one or more of an indication of each initial data unit of the set of initial data units associated with a successful reception, an indication of each initial data unit missing from the set of initial data units, an indication of a quantity of additional data units needed by the UE to decode the set of initial data units, an indication of a total quantity of successfully decoded initial data units from the set of initial data units, an indication of each data unit of the set of initial data units that is missing a sub-sequence number (sub-SN), or an indication of a rate adjustment command.

4. The method of claim 3, wherein a total quantity of the set of retransmission data units is based on the indication of the quantity of additional data units.

5. The method of claim 1, wherein:
the initial transmission parameter indicates the network coding function is enabled for the initial transmission;
the set of initial data units comprises two or more initial data units based on the network coding function being enabled for the initial transmission; and
the method further comprises generating a generator matrix associated with the network coding function based on receiving the set of initial data units.

6. The method of claim 5, further comprising determining a quantity threshold based on the generator matrix, wherein the set of initial data units satisfy the failure condition based on a total quantity of the set of initial data units being less than the quantity threshold.

7. The method of claim 5, further comprising decoding the set of initial data units based on the generator matrix to reconstruct a set of source segments for generating one or more data units, wherein the set of initial data units satisfy the failure condition based on a failure to reconstruct the set of source segments.

8. The method of claim 5, further comprising reconstructing one or more source segments of the set of source segments based on the set of retransmission data units and the set of initial data units,
wherein:
the retransmission parameter indicates the network coding function is enabled for the retransmission; and
the set of retransmission data units comprises one or more retransmission data units based on the network coding function being enabled for the retransmission.

9. The method of claim 8, wherein each retransmission data unit of the set of retransmission data units is a parity data unit.

10. The method of claim 8, wherein the set of initial data units and the set of retransmission data units comprise a same sequence number associated with a count value.

11. The method of claim 10, wherein the set of retransmission data units correspond to a set of source segments at the network device, each source segment of the set of source segments at the network device associated with a single source data unit.

12. The method of claim 10, wherein the set of retransmission data units correspond to a set of source segments at the network device, each source segment of the set of source segments at the network device associated with a plurality of source data units.

13. The method of claim 1, wherein:
the retransmission parameter indicates the network coding function is enabled for the retransmission and the initial transmission parameter indicates the network coding function is disabled for the initial transmission;
the set of retransmission data units comprises one or more retransmission data units based on the network coding function being enabled for the retransmission;
each retransmission data unit of the set of retransmission data units is a parity data unit; and
the method further comprises reconstructing one or more source segments of a set of source segments.

14. The method of claim 1, wherein the status data unit is one status data unit of a plurality of status data units that are periodically transmitted based on a timer.

15. The method of claim 1, wherein the status data unit is one status data unit of a plurality of status data units, each status data unit of the plurality of status data units being aperiodically transmitted based on receiving a respective trigger from the MRB.

16. An apparatus for wireless communications at a user equipment (UE), comprising:
a processor;
a memory coupled with the processor; and
instructions stored in the memory and operable, when executed by the processor, to cause the apparatus to:
receive, from a network device, radio resource control (RRC) signaling comprising an initial transmission parameter indicating whether a network coding function is enabled for an initial transmission from a first radio link control (RLC) entity associated with a multicast radio bearer (MRB) and a retransmission parameter indicating whether the network coding function is enabled for a retransmission from a second RLC entity associated with the MRB;
receive, from the first RLC entity of the network device, the initial transmission, the initial transmission comprising a set of initial data units;
transmit, to the network device, a status data unit comprising a set of status indicators, one or more status indicators of the set of status indicators indicating a reception failure based on the set of initial data units satisfying a failure condition; and
receive, from the second RLC entity of the network device, the retransmission comprising a set of retransmission data units, both the retransmission and the set of retransmission data units being received based on the one or more status indicators indicating the reception failure.

17. A method for wireless communication performed by a network device, comprising:
transmitting, to a user equipment (UE) from the network device, radio resource control (RRC) signaling comprising an initial transmission parameter indicating whether a network coding function is enabled for an initial transmission from a first radio link control (RLC) entity of the network device associated with a multicast radio bearer (MRB) and a retransmission parameter indicating whether the network coding function is enabled for a retransmission from a second RLC entity of the network device associated with the MRB;
transmitting, from the first RLC entity to the UE, a set of initial data units associated with the initial transmission;
receiving, from the UE, a status data unit comprising a set of status indicators, one or more status indicators of the set of status indicators indicating a reception failure; and
transmitting, from the second RLC entity to the UE, a set of retransmission data units associated with the retransmission, the set of retransmission data units being transmitted based on the one or more status indicators indicating the reception failure.

18. The method of claim 17, wherein the set of status indicators comprise one or more of an indication of each initial data unit of the set of initial data units associated with a successful reception, an indication for each initial data unit missing from the set of initial data units, an indication of a quantity of additional data units needed by the UE to decode the set of initial data units, an indication of a total quantity of successfully decoded initial data units from the set of initial data units, an indication of each initial data unit of the set of initial data units that is missing a sub-sequence number (sub-SN), or an indication of a rate adjustment command.

19. The method of claim 18, wherein a total quantity of the set of retransmission data units is based on the indication of the quantity of additional data units.

20. The method of claim 17, wherein:
the RRC signaling indicates the network coding function is enabled for the initial transmission; and
the set of initial data units comprises two or more initial data units based on the network coding function being enabled for the initial transmission.

21. The method of claim 20, further comprising:
segmenting, at a packet data convergence protocol (PDCP) entity of the network device, a source data unit; and
encoding, at the PDCP entity of the network device, the set of initial data units based on applying the network coding function to a first set of source segments associated with the source data unit,
wherein:
each initial data unit of the set of initial data units comprises a sequence number associated with the source data unit and a different respective sub-sequence number of a plurality of sub-sequence numbers; and
a total quantity of sub-sequence numbers is equal to a total quantity of the set of initial data units.

22. The method of claim 21, wherein a total quantity of the first set of source segments is less than the total quantity of the set of initial data units.

23. The method of claim 21, wherein:
the RRC signaling indicates the network coding function is enabled for the retransmission; and
the set of retransmission data units comprises one or more retransmission data units based on the network coding function being enabled for the retransmission.

24. The method of claim 23, further comprising constructing, at the PDCP entity, a set of parity data units from one or more source segments of the first set of source segments,
wherein:
each source segment of the one or more source segments corresponding to a negative acknowledgement associated with a different respective status indicator of the set of status indicators; and
each retransmission data unit of the set of retransmission data units is a different respective parity data unit of the set of parity data units.

25. The method of claim 23, further comprising:
segmenting, at the PDCP entity, one or more source data units; and
encoding, at the PDCP entity, the set of retransmission units based on applying the network coding function to a second set of source segments associated with the one or more source data units.

26. The method of claim 17, further comprising constructing, at a packet data convergence protocol (PDCP) entity of the network device, a set of parity data units from one or more source segments of a set of source segments,
wherein:
the RRC signaling indicates the network coding function is enabled for the retransmission and the network coding function is disabled for the initial transmission;
the set of retransmission data units comprises one or more retransmission data units based on the network coding function being enabled for the retransmission;
each source segment of the set of source segments corresponding to a negative acknowledgement associated with a different respective status indicator of the set of status indicators; and
each retransmission data unit of the set of retransmission data units is a different respective parity data unit of the set of parity data units.

27. The method of claim 17, further comprising:
transmitting, to the UE, a configuration for a periodic feedback timer; and
receiving the status data unit based on an expiration of the periodic feedback timer.

28. The method of claim 17, further comprising:
transmitting, to the UE, a signal to trigger a transmission of the status data unit; and
receiving, from the UE, the status data unit based on transmitting the trigger.

29. The method of claim 17, further comprising scheduling the retransmission regardless of receiving the status data unit.

30. An apparatus for wireless communications at a network device, comprising:
a processor;
a memory coupled with the processor; and
instructions stored in the memory and operable, when executed by the processor, to cause the apparatus to:
transmit, to a user equipment (UE) from the network device, radio resource control (RRC) signaling comprising an initial transmission parameter indicating whether a network coding function is enabled for an initial transmission from a first radio link control (RLC) entity of the network device associated with a multicast radio bearer (MRB) and a retransmission parameter indicating whether the network coding function is enabled for a retransmission from a second RLC entity of the network device associated with the MRB;
transmit, from the first RLC entity to the UE, a set of initial data units associated with the initial transmission;
receive, from the UE, a status data unit comprising a set of status indicators, one or more status indicators of the set of status indicators indicating a reception failure; and
transmit, from the second RLC entity to the UE, a set of retransmission data units associated with the retransmission, the set of retransmission data units being transmitted based on the one or more status indicators indicating the reception failure.
